(19) United States
(12) Patent Application Publication
(10) Pub. No.: US 2025/0315161 A1
(43) Pub. Date: Oct. 9, 2025

(54) System and Method for Data Compaction with Adaptive Codebook Statistical Estimates and Distributed Maintenance

(71) Applicant: AtomBeam Technologies Inc., Moraga, CA (US)

(72) Inventors: Joshua Cooper, Columbia, SC (US); Charles Yeomans, Orinda, CA (US)

(21) Appl. No.: 19/245,391

(22) Filed: Jun. 22, 2025

Related U.S. Application Data
(63) Continuation-in-part of application No. 18/520,473, filed on Nov. 27, 2023, now Pat. No. 12,373,101.
Application No. 18/520,473 is a continuation of application No. 18/295,238, filed on Apr. 3, 2023, now Pat. No. 11,928,335.
Application No. 18/295,238 is a continuation of application No. 17/974,230, filed on Oct. 26, 2022, now Pat. No. 11,687,241.
Application No. 17/974,230 is a continuation-in-part of application No. 17/884,470, filed on Aug. 9, 2022, now abandoned.
(60) Provisional application No. 63/232,050, filed on Aug. 11, 2021.

(51) Int. Cl. G06F 3/06; H03M 7/30

(52) U.S. Cl. CPC G06F 3/0608; G06F 3/0623; G06F 3/0659; G06F 3/067; H03M 7/6005; H03M 7/6011

(57) ABSTRACT

A system and method for data compaction with adaptive codebook statistical estimates. Training data sets determine sourceblock frequencies while a dynamic mismatch probability system continuously refines estimates based on observed patterns. Context-aware handling selects appropriate secondary encoding methods for different data types (text, binary, image, executable). Machine learning models predict optimal mismatch probabilities from extracted features. Edge-optimized training enables codebook development on resource-constrained devices with intelligent resource management. Differential updates transmit only changes between codebook versions, minimizing bandwidth usage. Federated learning enables multiple devices to contribute to shared codebooks while maintaining data privacy. A secure synchronization protocol with authentication and verification ensures codebook consistency. The distributed maintenance method provides systematic validation, conflict resolution, and optimization across device networks, enabling efficient encoding across heterogeneous systems.

### CROSS-REFERENCE TO RELATED APPLICATIONS

Priority is claimed in the application data sheet to the following patents or patent applications, each of which is expressly incorporated herein by reference in its entirety:
Ser. No. 18/520,473
Ser. No. 18/295,238
Ser. No. 17/974,230
Ser. No. 17/884,470
63/232,050

### BACKGROUND OF THE INVENTION

### Field of the Invention

The present invention is in the field of computer data encoding, and in particular the usage of adaptive, context-aware encoding techniques for enhanced security, efficient distribution, and compaction of data across heterogeneous computing environments.

### Discussion of the State of the Art

As computers become an ever-greater part of our lives, data storage and efficient transmission have become critical limiting factors worldwide. Prior to about 2010, the growth of data storage far exceeded the growth in storage demand. Current estimates are that data storage demand will reach 175 zettabytes by 2025, yet global manufacturing capacity for physical storage remains orders of magnitude lower. This gap continues to widen with the proliferation of edge devices, IoT sensors, and distributed computing systems that generate unprecedented volumes of data.

While traditional data compression offers some relief with typical compression ratios of 2:1, it falls short for modern multi-media data types and distributed computing paradigms. Even assuming a doubling of storage capacity, conventional compression cannot solve the global data storage problem. Additionally, as distributed systems become more prevalent, the challenges of maintaining consistent compression models across heterogeneous devices has emerged as a significant limitation.

Transmission bandwidth continues to be a bottleneck, especially in edge computing scenarios where limited connectivity or power constraints restrict data transfer capabilities. Even with high-bandwidth connections between data centers, the sheer volume of data being transferred necessitates more efficient encoding approaches.

Furthermore, the security of data, both stored and in transit, remains a critical concern. Current approaches often treat security as a separate layer from compression, resulting in inefficient processing and increased computational overhead.

Entropy encoding methods can be used to partially solve some of these data compaction issues. However, existing entropy encoding methods either fail to account for, or inefficiently encode, data that has not previously been processed by the encoding method, and thus lead to inefficient compaction of data in many cases. Moreover, these methods typically employ static, non-adaptive approaches that cannot adjust to changing data patterns or different data types, and lack mechanisms for efficient distribution and synchronization across device networks.

What is needed is an advanced system and method for data compaction with adaptive codebook statistical estimates that dynamically responds to data characteristics, efficiently handles diverse data types, operates effectively across resource-constrained distributed environments, and maintains consistency through intelligent synchronization mechanisms.

### SUMMARY OF THE INVENTION

The inventor has developed an enhanced system and method for compacting data that uses adaptive mismatch probability estimation to improve entropy encoding methods across distributed environments. Training data sets are analyzed to determine the frequency of occurrence of each sourceblock. A dynamic mismatch probability system continuously refines probability estimates based on observed data patterns and real-time analysis. Context-aware mismatch handling selects appropriate secondary encoding methods based on detected data types (text, binary, image, or executable), significantly improving compression efficiency for diverse data types.

According to a preferred embodiment, a computer system for encoding data using mismatch probability estimation is disclosed, comprising: a hardware memory, wherein the computer system is configured to execute software instructions stored on nontransitory machine-readable storage media that: receive a training data set for encoding, the training data set comprising sourceblocks of data; determine a frequency of occurrence of each sourceblock of the training data set; calculate a mismatch probability estimate comprising a probability that any given sourceblock in a non-training data set to be later received for encoding will not be a sourceblock that was contained in the training data set, wherein the mismatch probability estimate is dynamically adjusted based on observed data patterns; generate a mismatch sourceblock representing sourceblocks that were not contained in the training data set, and assign the mismatch probability estimate to the mismatch sourceblock as the frequency of occurrence of the mismatch sourceblock; generate a codebook from the sourceblocks of the training data set and the mismatch sourceblock using an entropy encoding method wherein codewords are assigned to each sourceblock based on its frequency of occurrence; and apply context-aware mismatch handling to select an appropriate secondary encoding method based on detected data type.

The system implements machine learning models that predict optimal mismatch probabilities from extracted features, monitors real-time data patterns during encoding, and applies an adaptive exponentially-weighted moving average formula to calculate updated mismatch probability estimates. Edge-optimized training enables codebook development on resource-constrained devices with intelligent resource management. Differential updates transmit only changes between codebook versions, minimizing bandwidth usage.

The system further implements a federated codebook learning approach that enables multiple devices to contribute to shared codebooks while maintaining data privacy, employing techniques including differential privacy, secure aggregation, and knowledge distillation. A secure synchronization protocol with authentication, version exchange, and verification ensures codebook consistency. The distributed maintenance method provides systematic validation, conflict resolution, and update distribution across device networks.

According to another preferred embodiment, a computer-implemented method for encoding data using mismatch probability estimation is disclosed, comprising the steps of: using a hardware memory, wherein the computer system is configured to execute software instructions stored on nontransitory machine-readable storage media that: receives a training data set for encoding, the training data set comprising sourceblocks of data; determines a frequency of occurrence of each sourceblock of the training data set; calculates a mismatch probability estimate comprising a probability that any given sourceblock in a non-training data set to be later received for encoding will not be a sourceblock that was contained in the training data set, wherein the calculation implements a machine learning model trained to predict optimal mismatch probabilities based on data characteristics; generates a mismatch sourceblock representing sourceblocks that were not contained in the training data set, and assigns the mismatch probability estimate to the mismatch sourceblock as the frequency of occurrence of the mismatch sourceblock; generates a codebook from the sourceblocks of the training data set and the mismatch sourceblock using an entropy encoding method wherein codewords are assigned to each sourceblock based on its frequency of occurrence; and maintains codebook consistency across distributed devices through periodic validation and differential updates.

The method further includes analyzing the context of the data to determine its type, selecting context-specific secondary encoding methods optimized for the determined data type, monitoring real-time data patterns, enabling codebook training on resource-constrained edge devices, generating differential updates containing only changes between codebook versions, implementing secure synchronization protocols, and maintaining distributed codebooks through systematic validation and optimization processes.

This enhanced approach significantly improves upon traditional entropy encoding by dynamically adapting to data characteristics, efficiently handling diverse data types, operating effectively in distributed environments, and maintaining consistency through intelligent synchronization mechanisms.

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment of the invention.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is a flow diagram illustrating the use of a data encoding system used to recursively encode data to further reduce data size.

FIG. 19 is an exemplary system architecture of a data encoding system used for cyber security purposes.

FIG. 20 is a flow diagram of an exemplary method used to detect anomalies in received encoded data and producing a warning.

FIG. 21 is a flow diagram of a data encoding system used for Distributed Denial of Service (DDoS) attack denial.

FIG. 22 is an exemplary system architecture of a data encoding system used for data mining and analysis purposes.

FIG. 23 is a flow diagram of an exemplary method used to enable high-speed data mining of repetitive data.

FIG. 24 is an exemplary system architecture of a data encoding system used for remote software and firmware updates.

FIG. 25 is a flow diagram of an exemplary method used to encode and transfer software and firmware updates to a device for installation, for the purposes of reduced bandwidth consumption.

FIG. 26 is an exemplary system architecture of a data encoding system used for large-scale software installation such as operating systems.

FIG. 27 is a flow diagram of an exemplary method used to encode new software and operating system installations for reduced bandwidth required for transference.

FIG. 28 is a block diagram of an exemplary system architecture of a codebook training system for a data encoding system, according to an embodiment.

FIG. 29 is a block diagram of an exemplary architecture for a codebook training module, according to an embodiment.

FIG. 30 is a block diagram of another embodiment of the codebook training system using a distributed architecture and a modified training module.

FIG. 31 is a method diagram illustrating the steps involved in using an embodiment of the codebook training system to update a codebook.

FIG. 32 is an exemplary system architecture for an encoding system with multiple codebooks.

FIG. 33 is a flow diagram describing an exemplary algorithm for encoding of data using multiple codebooks.

FIG. 34 is a diagram showing an exemplary control byte used to combine sourcepackets encoded with multiple codebooks.

FIG. 35 is a diagram showing an exemplary codebook shuffling method.

FIG. 36 is a block diagram of an exemplary system architecture for encoding data using mismatch probability estimates, according to an embodiment.

FIG. 37 is a diagram illustrating an exemplary method for codebook generation from a training data set.

FIG. 38 is a diagram illustrating an exemplary encoding using a codebook and secondary encoding.

FIG. 39 is a block diagram illustrating an exemplary system architecture for a dynamic mismatch probability estimation according to an embodiment of the invention.

FIG. 40 is a block diagram illustrating a machine learning-based mismatch probability estimation system, according to an embodiment of the invention.

FIG. 41 is a block diagram illustrating a context-aware mismatch handling system that represents a significant enhancement to the mismatch handling approach.

FIG. 42 is a method diagram for an adaptive mismatch probability calculation that significantly advances beyond static probability estimation approaches.

FIG. 43 is a block diagram illustrating an innovative edge-optimized codebook training system.

FIG. 44 is a block diagram illustrating a differential codebook updating system.

FIG. 45 is a block diagram illustrating a federated codebook learning system over the centralized training approach.

FIG. 46 is a block diagram illustrating a comprehensive codebook synchronization protocol.

FIG. 47 is a method diagram illustrating a comprehensive method for distributed codebook maintenance that addresses critical requirements for maintaining consistency, resolving conflicts, and optimizing performance across a network of devices using the encoding system.

FIG. 48 illustrates an exemplary computing environment on which an embodiment described herein may be implemented, in full or in part.

### DETAILED DESCRIPTION OF THE DRAWING FIGURES

The inventor has conceived, and reduced to practice, a system and method for data compaction with codebook statistical estimates to improve entropy encoding methods to account for, and efficiently handle, previously-unseen data in data to be compacted. Training data sets are analyzed to determine the frequency of occurrence of each sourceblock in the training data sets. A mismatch probability estimate is calculated comprising an estimated frequency at which any given data sourceblock received during encoding will not have a codeword in the codebook. Entropy encoding is used to generate codebooks comprising codewords for data sourceblocks based on the frequency of occurrence of each sourceblock. A “mismatch codeword” is inserted into the codebook based on the mismatch probability estimate to represent those cases when a block of data to be encoded does not have a codeword in the codebook. During encoding, if a mismatch occurs, a secondary encoding process is used to encode the mismatched sourceblock.

Entropy encoding methods (also known as entropy coding methods) are lossless data compression methods which replace fixed-length data inputs with variable-length prefix-free codewords based on the frequency of their occurrence within a given distribution. This reduces the number of bits required to store the data inputs, limited by the entropy of the total data set. The most well-known entropy encoding method is Huffman coding, which will be used in the examples herein.

Because any lossless data compression method must have a code length sufficient to account for the entropy of the data set, entropy encoding is most compact where the entropy of the data set is small. However, smaller entropy in a data set means that, by definition, the data set contains fewer variations of the data. So, the smaller the entropy of a data set used to create a codebook using an entropy encoding method, the larger is the probability that some piece of data to be encoded will not be found in that codebook. Adding new data to the codebook leads to inefficiencies that undermine the use of a low-entropy data set to create the codebook.

This disadvantage of entropy encoding methods can be overcome by mismatch probability estimation, wherein the probability of encountering data that is not in the codebook is calculated in advance, and a special “mismatch codework” is incorporated into the codebook (the primary encoding algorithm) to represent the expected frequency of encountering previously-unencountered data. When previously-unencountered data is encountered during encoding, attempting to encode the previously-unencountered data results in the mismatch codeword, which triggers a secondary encoding algorithm to encode that previously-unencountered data. The secondary encoding algorithm may result in a less-than-optimal encoding of the previously-unencountered data, but the efficiencies of using a low-entropy primary encoding make up for the inefficiencies of the secondary encoding algorithm. Because the use of the secondary encoding algorithm has been accounted for in the primary encoding algorithm by the mismatch probability estimation, the overall efficiency of compaction is improved over other entropy encoding methods.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

The term “bit” refers to the smallest unit of information that can be stored or transmitted. It is in the form of a binary digit (either 0 or 1). In terms of hardware, the bit is represented as an electrical signal that is either off (representing 0) or on (representing 1).

The term “byte” refers to a series of bits exactly eight bits in length.

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless,” in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio,” and as used herein all mean the size of the original data relative to the size of the compressed data (e.g., if the new data is 70% of the size of the original, then the deflation/compression ratio is 70% or 0.7.)

The term “data” means information in any computer-readable form.

The term “data set” refers to a grouping of data for a particular purpose. One example of a data set might be a word processing file containing text and formatting information.

The term “effective compression” or “effective compression ratio” refers to the additional amount data that can be stored using the method herein described versus conventional data storage methods. Although the method herein described is not data compression, per se, expressing the additional capacity in terms of compression is a useful comparison.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code or “codeword” to a sourceblock in the library plus an indication of that sourceblock's location in a particular data set.

### Conceptual Architecture

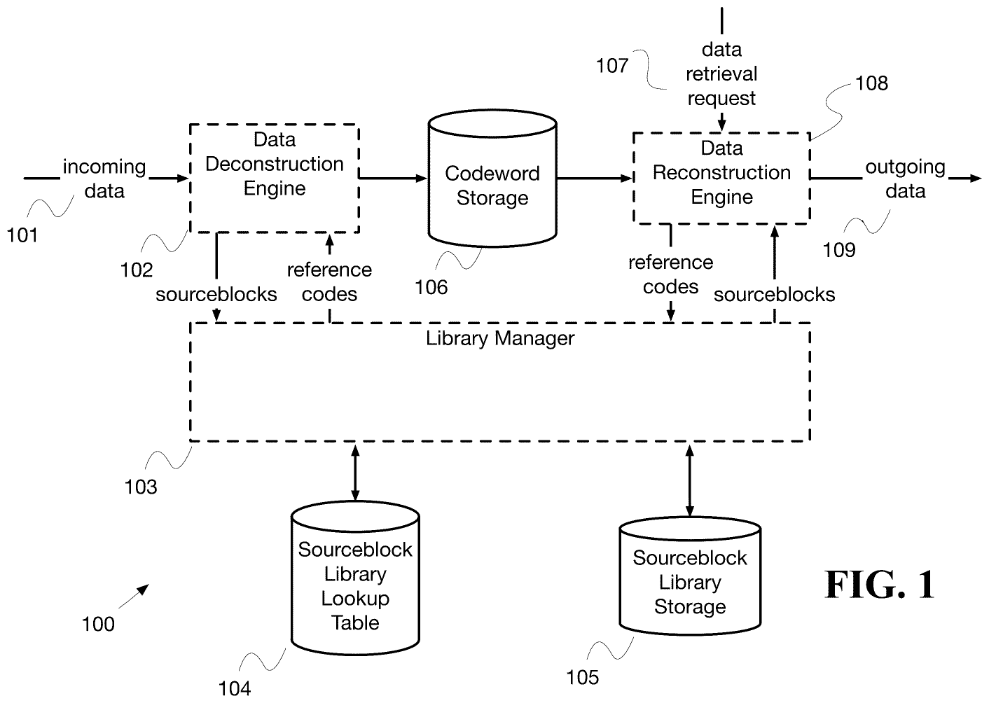

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

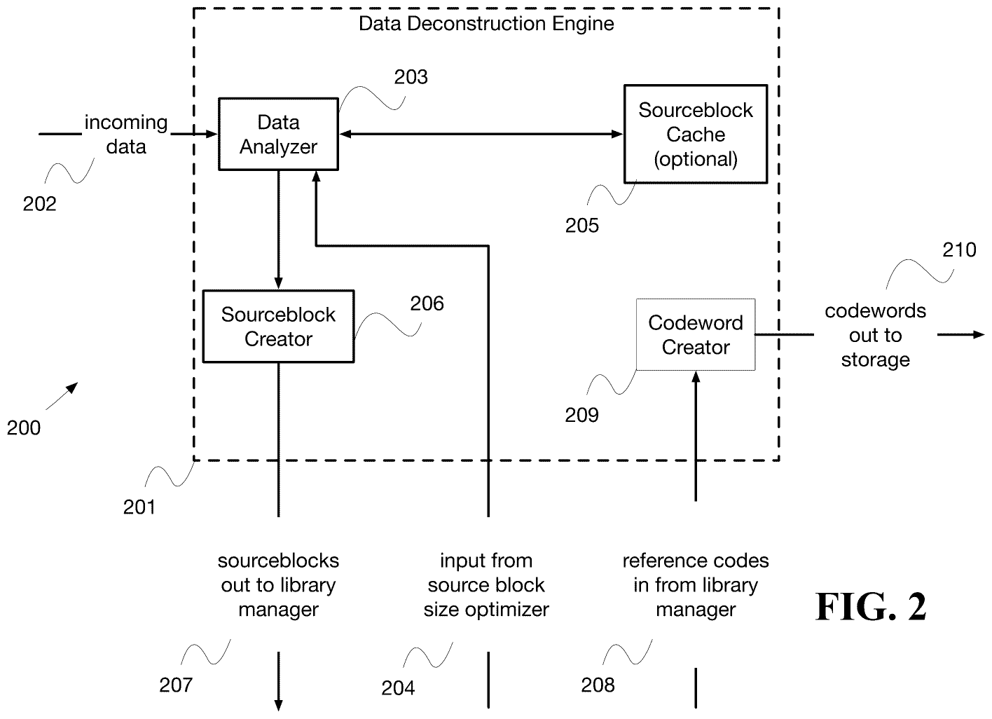

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

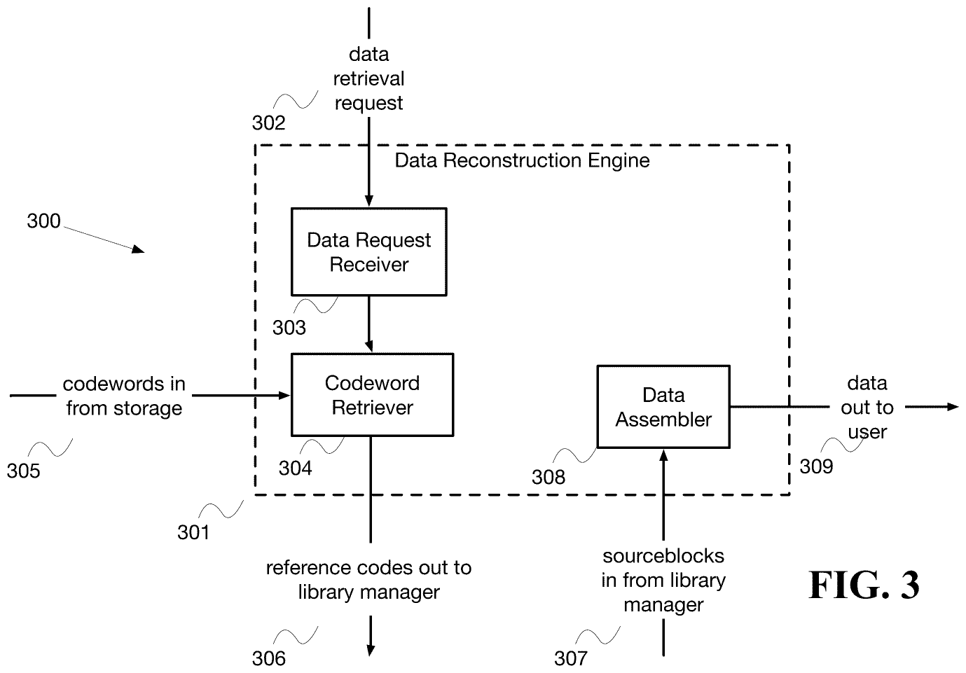

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

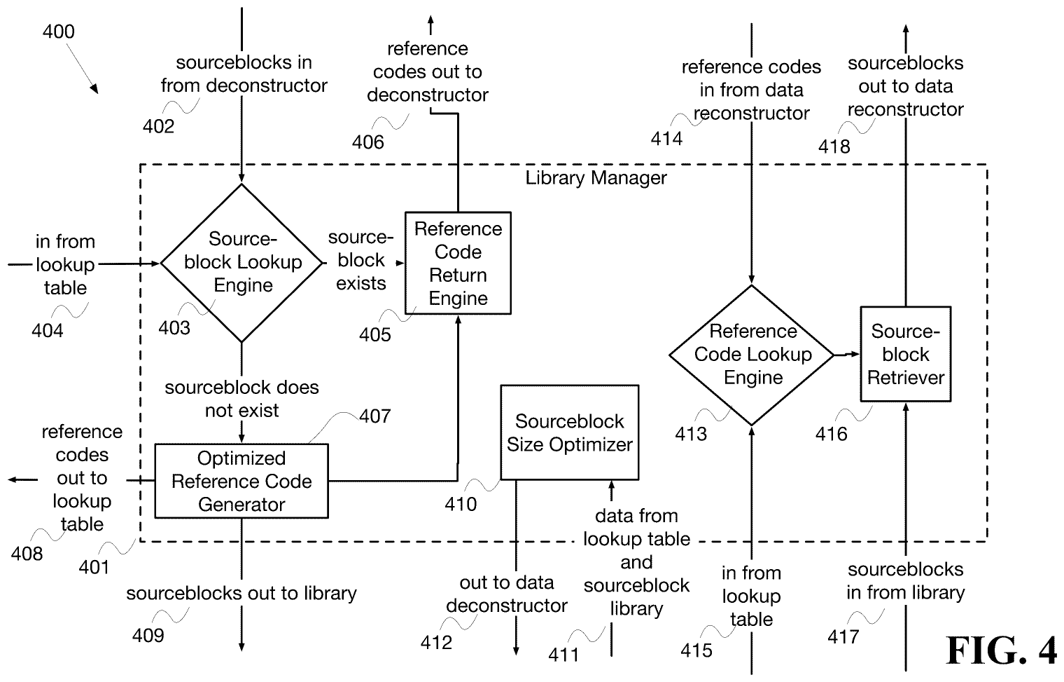

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

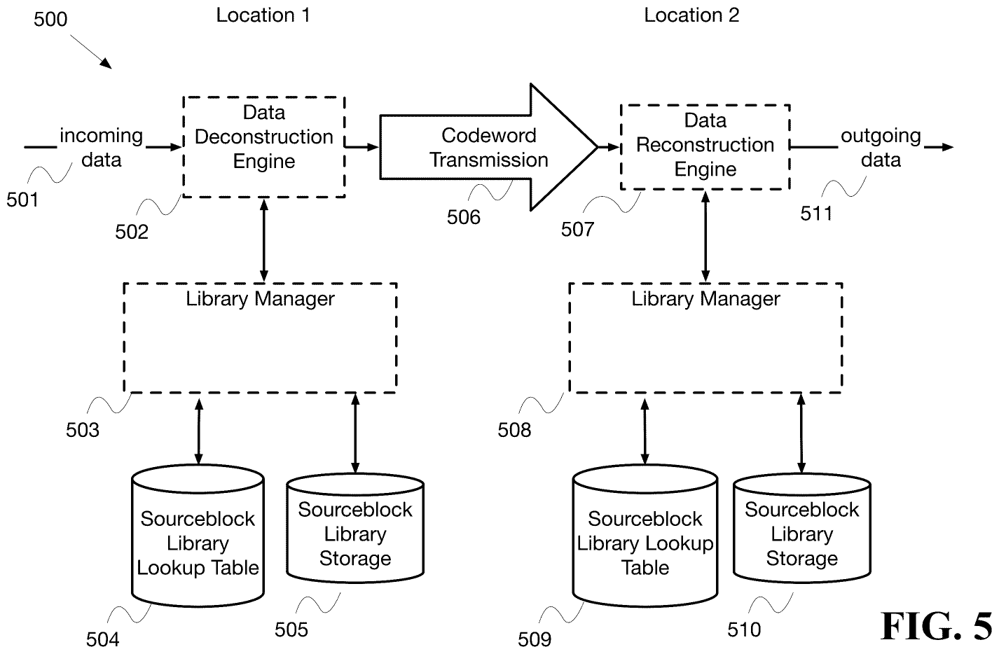

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2 and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

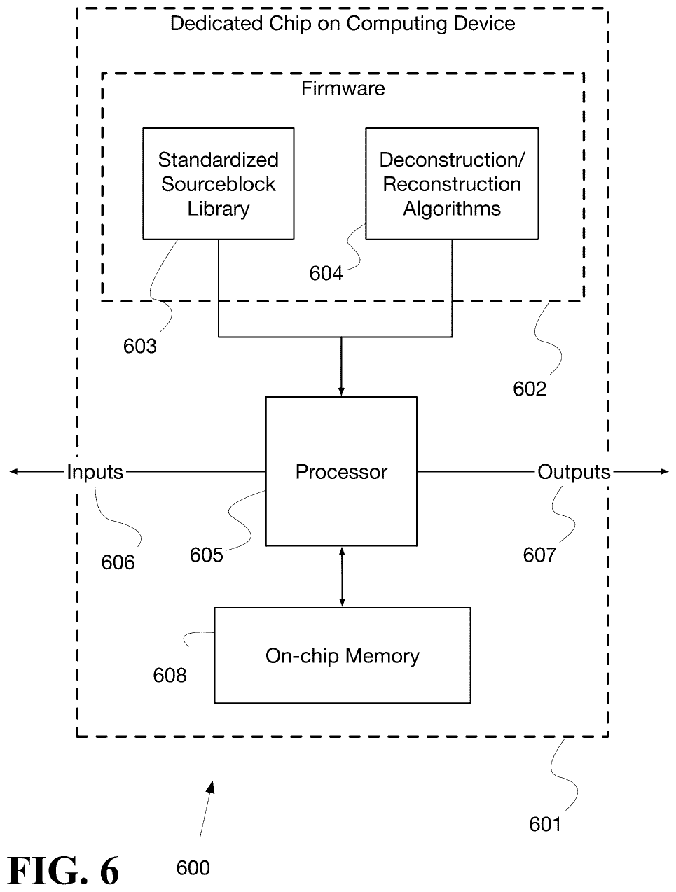

FIG. 6 is a diagram showing an embodiment 600 in which a standardized version of a sourceblock library 603 and associated algorithms 604 would be encoded as firmware 602 on a dedicated processing chip 601 included as part of the hardware of a plurality of devices 600. Contained on dedicated chip 601 would be a firmware area 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device's 600 primary processors. Any device equipped with this embodiment would be able to store and transmit data in a highly optimized, bandwidth-efficient format with any other device equipped with this embodiment.

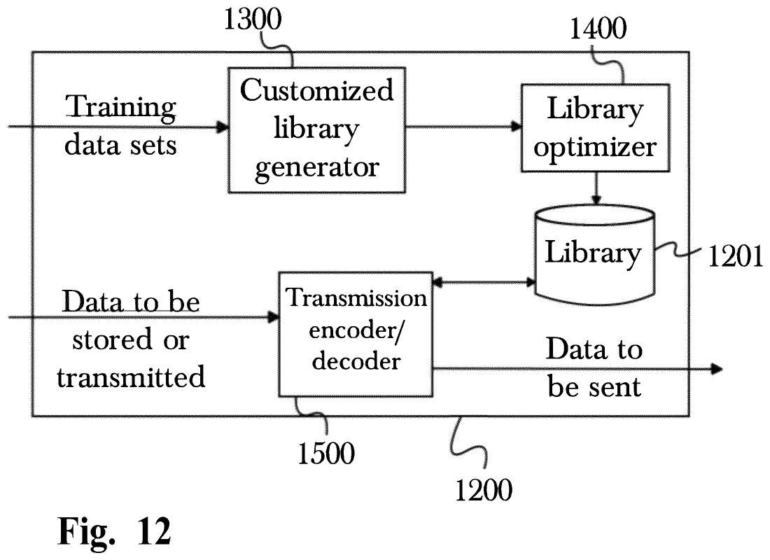

FIG. 12 is a diagram showing an exemplary system architecture 1200, according to a preferred embodiment of the invention. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is Re bit/s and the decoding rate is R_{D} bit/s, and the transmission speed is S bit/s, the compress-send-decompress time will be

$${T}_{o l d} = \frac{N}{{R}_{C}} + \frac{N}{C S} + \frac{N}{C {R}_{D}}$$

while the transmit-while-coding time for system 1200 will be (assuming that encoding and decoding happen at least as quickly as network latency):

$${T}_{n e w} = \frac{{N}_{p}}{CS}$$

so that the total data transit time improvement factor is

$$\frac{{T}_{o l d}}{{T}_{n e w}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1.$$

This is a reasonable scenario given that typical values in real-world practice are C=0.32, R_{C}=1.1·10¹², R_{D}=4.2·10¹², S=10¹¹, giving

$$\frac{CS}{{R}_{C}} + \frac{S}{{R}_{D}} = 0.0 \; 53 … ,$$

such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{t p}{CS}$$

since encoding and decoding occur concurrently with data transmission. On the other hand, the latency associated with classical compression is

$${delay}_{priorart} = \frac{N}{{R}_{C}} + \frac{N}{C S} + \frac{N}{C {R}_{D}}$$

where N is the packet/file size. Even with the generous values chosen above as well as N=512K, t=10, and p=1.05, this results in delayᵢₙᵥₑₙₜᵢₒₙ≈3.3·10⁻¹⁰ while delayₚᵣᵢₒᵣₐᵣₜ≈1.3·10⁻⁷, a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

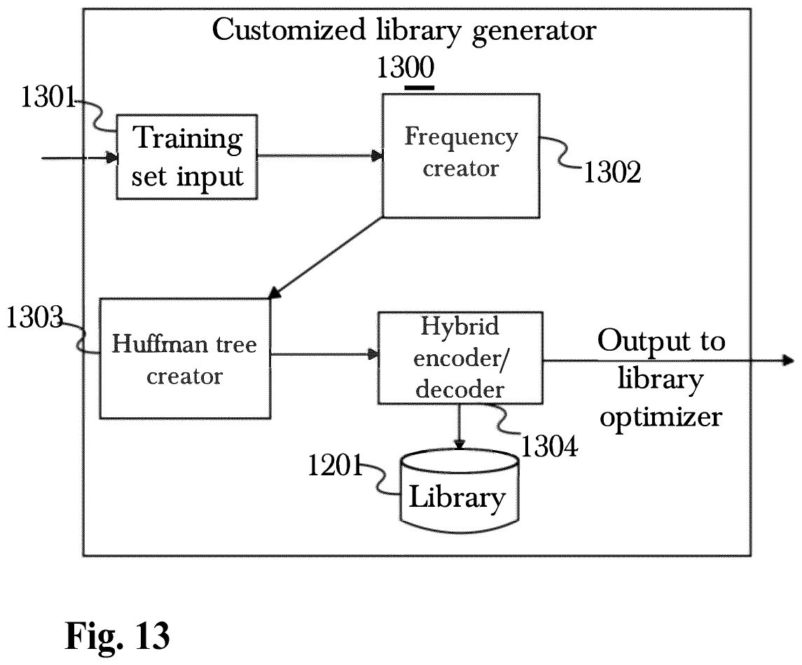

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

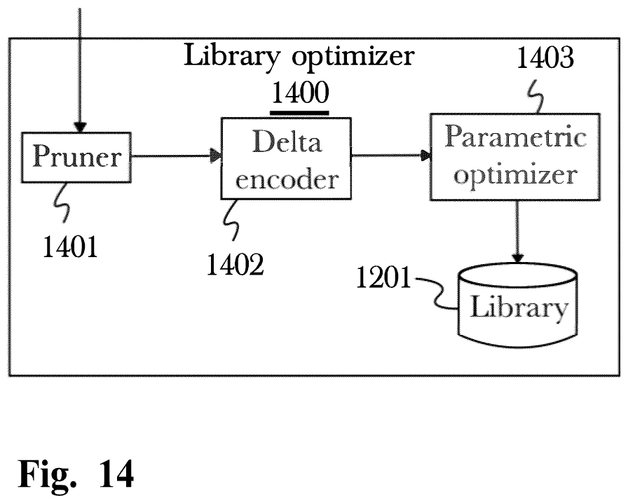

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

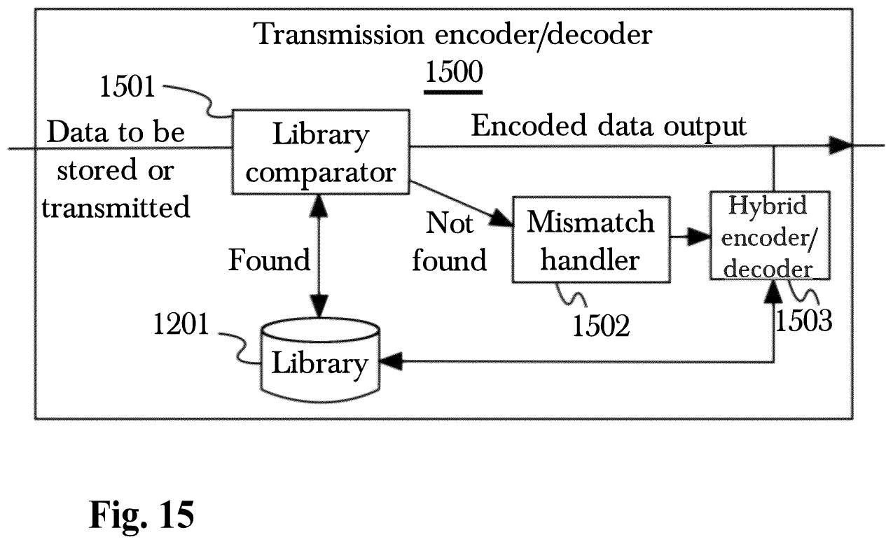

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword using shorter block-length encoding for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

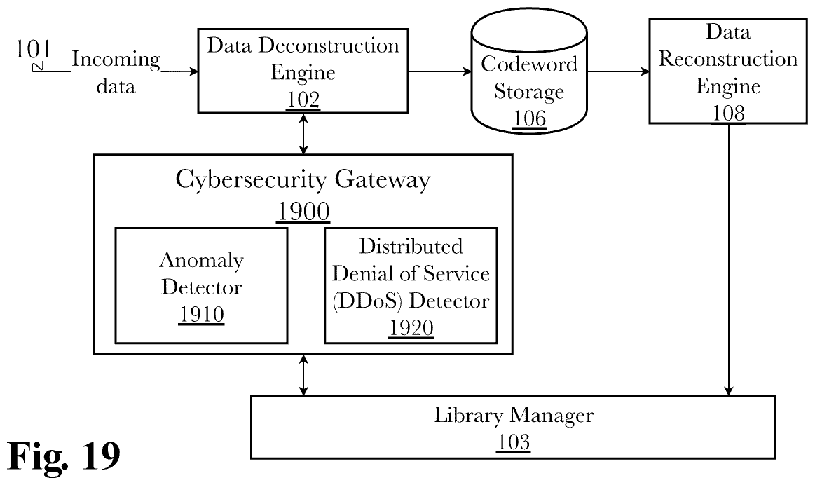

FIG. 19 is an exemplary system architecture of a data encoding system used for cyber security purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process, and may be queried by a data reconstruction engine 108 which may reconstruct the original data from the codewords, using a library manager 103. However, a cybersecurity gateway 1900 is present, communicating in-between a library manager 103 and a deconstruction engine 102, and containing an anomaly detector 1910 and distributed denial of service (DDoS) detector 1920. The anomaly detector examines incoming data to determine whether there is a disproportionate number of incoming reference codes that do not match reference codes in the existing library. A disproportionate number of non-matching reference codes may indicate that data is being received from an unknown source, of an unknown type, or contains unexpected (possibly malicious) data. If the disproportionate number of non-matching reference codes exceeds an established threshold or persists for a certain length of time, the anomaly detector 1910 raises a warning to a system administrator. Likewise, the DDoS detector 1920 examines incoming data to determine whether there is a disproportionate amount of repetitive data. A disproportionate amount of repetitive data may indicate that a DDoS attack is in progress. If the disproportionate amount of repetitive data exceeds an established threshold or persists for a certain length of time, the DDoS detector 1910 raises a warning to a system administrator. In this way, a data encoding system may detect and warn users of, or help mitigate, common cyber-attacks that result from a flow of unexpected and potentially harmful data, or attacks that result from a flow of too much irrelevant data meant to slow down a network or system, as in the case of a DDoS attack.

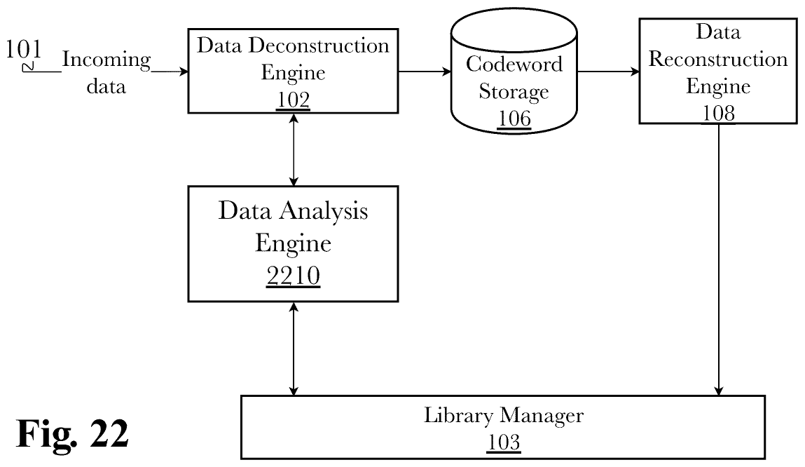

FIG. 22 is an exemplary system architecture of a data encoding system used for data mining and analysis purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process and may be queried by a data reconstruction engine 108 which may reconstruct the original data from the codewords, using a library manager 103. A data analysis engine 2210, typically operating while the system is otherwise idle, sends requests for data to the data reconstruction engine 108, which retrieves the codewords representing the requested data from codeword storage 106, reconstructs them into the data represented by the codewords, and send the reconstructed data to the data analysis engine 2210 for analysis and extraction of useful data (i.e., data mining). Because the speed of reconstruction is significantly faster than decompression using traditional compression technologies (i.e., significantly less decompression latency), this approach makes data mining feasible. Very often, data stored using traditional compression is not mined precisely because decompression lag makes it unfeasible, especially during shorter periods of system idleness. Increasing the speed of data reconstruction broadens the circumstances under which data mining of stored data is feasible.

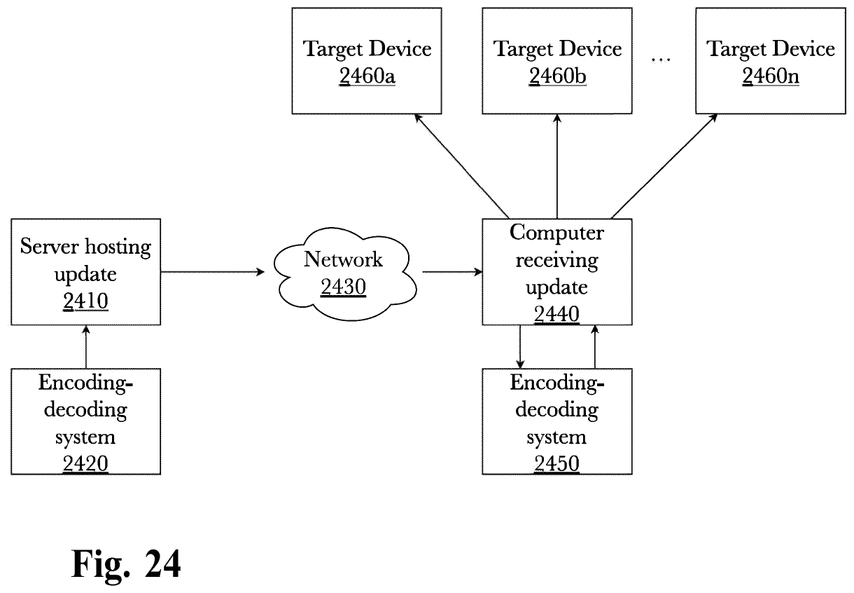

FIG. 24 is an exemplary system architecture of a data encoding system used for remote software and firmware updates. Software and firmware updates typically require smaller, but more frequent, file transfers. A server which hosts a software or firmware update 2410 may host an encoding-decoding system 2420, allowing for data to be encoded into, and decoded from, sourceblocks or codewords, as disclosed in previous figures. Such a server may possess a software update, operating system update, firmware update, device driver update, or any other form of software update, which in some cases may be minor changes to a file, but nevertheless necessitate sending the new, completed file to the recipient. Such a server is connected over a network 2430, which is further connected to a recipient computer 2440, which may be connected to a server 2410 for receiving such an update to its system. In this instance, the recipient device 2440 also hosts the encoding and decoding system 2450, along with a codebook or library of reference codes that the hosting server 2410 also shares. The updates are retrieved from storage at the hosting server 2410 in the form of codewords, transferred over the network 2430 in the form of codewords, and reconstructed on the receiving computer 2440. In this way, a far smaller file size, and smaller total update size, may be sent over a network. The receiving computer 2440 may then install the updates on any number of target computing devices 2460a-n, using a local network or other high-bandwidth connection.

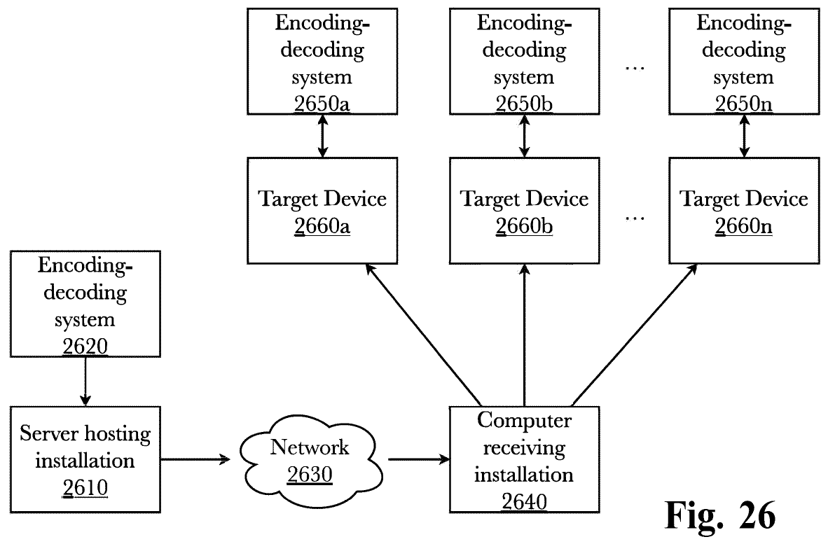

FIG. 26 is an exemplary system architecture of a data encoding system used for large-scale software installation such as operating systems. Large-scale software installations typically require very large, but infrequent, file transfers. A server which hosts an installable software 2610 may host an encoding-decoding system 2620, allowing for data to be encoded into, and decoded from, sourceblocks or codewords, as disclosed in previous figures. The files for the large scale software installation are hosted on the server 2610, which is connected over a network 2630 to a recipient computer 2640. In this instance, the encoding and decoding system 2650a-n is stored on or connected to one or more target devices 2660a-n, along with a codebook or library of reference codes that the hosting server 2610 shares. The software is retrieved from storage at the hosting server 2610 in the form of codewords and transferred over the network 2630 in the form of codewords to the receiving computer 2640. However, instead of being reconstructed at the receiving computer 2640, the codewords are transmitted to one or more target computing devices, and reconstructed and installed directly on the target devices 2660a-n. In this way, a far smaller file size, and smaller total update size, may be sent over a network or transferred between computing devices, even where the network 2630 between the receiving computer 2640 and target devices 2660a-n is low bandwidth, or where there are many target devices 2660a-n.

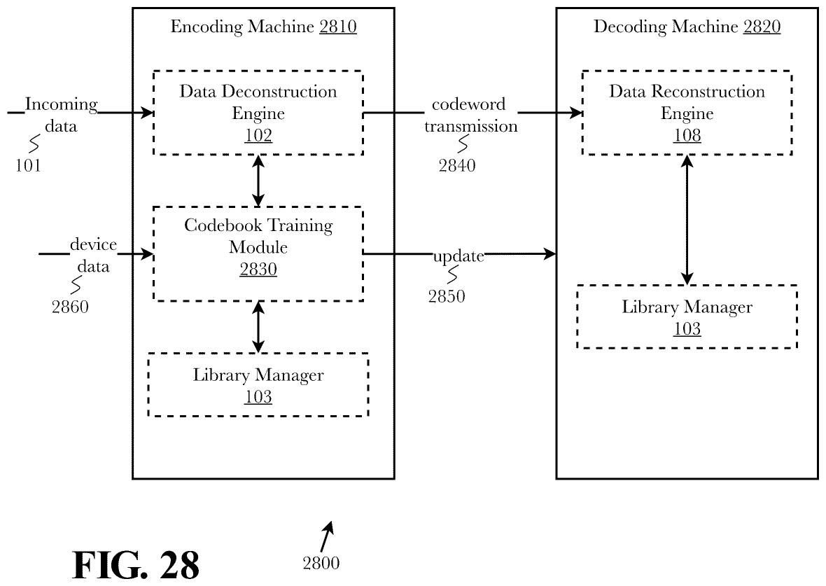

FIG. 28 is a block diagram of an exemplary system architecture 2800 of a codebook training system for a data encoding system, according to an embodiment. According to this embodiment, two separate machines may be used for encoding 2810 and decoding 2820. Much like in FIG. 1, incoming data 101 to be deconstructed is sent to a data deconstruction engine 102 residing on encoding machine 2810, which may attempt to deconstruct the data and turn it into a collection of codewords using a library manager 103. Codewords may be transmitted 2840 to a data reconstruction engine 108 residing on decoding machine 2820, which may reconstruct the original data from the codewords, using a library manager 103. However, according to this embodiment, a codebook training module 2830 is present on the decoding machine 2810, communicating in-between a library manager 103 and a deconstruction engine 102. According to other embodiments, codebook training module 2830 may reside instead on decoding machine 2820 if the machine has enough computing resources available; which machine the module 2830 is located on may depend on the system user's architecture and network structure. Codebook training module 2830 may send requests for data to the data reconstruction engine 2810, which routes incoming data 101 to codebook training module 2830. Codebook training module 2830 may perform analyses on the requested data in order to gather information about the distribution of incoming data 101 as well as monitor the encoding/decoding model performance. Additionally, codebook training module 2830 may also request and receive device data 2860 to supervise network connected devices and their processes and, according to some embodiments, to allocate training resources when requested by devices running the encoding system. Devices may include, but are not limited to, encoding and decoding machines, training machines, sensors, mobile computer devices, and Internet-of-things (“IoT”) devices. Based on the results of the analyses, the codebook training module 2830 may create a new training dataset from a subset of the requested data in order to counteract the effects of data drift on the encoding/decoding models, and then publish updated 2850 codebooks to both the encoding machine 2810 and decoding machine 2820.

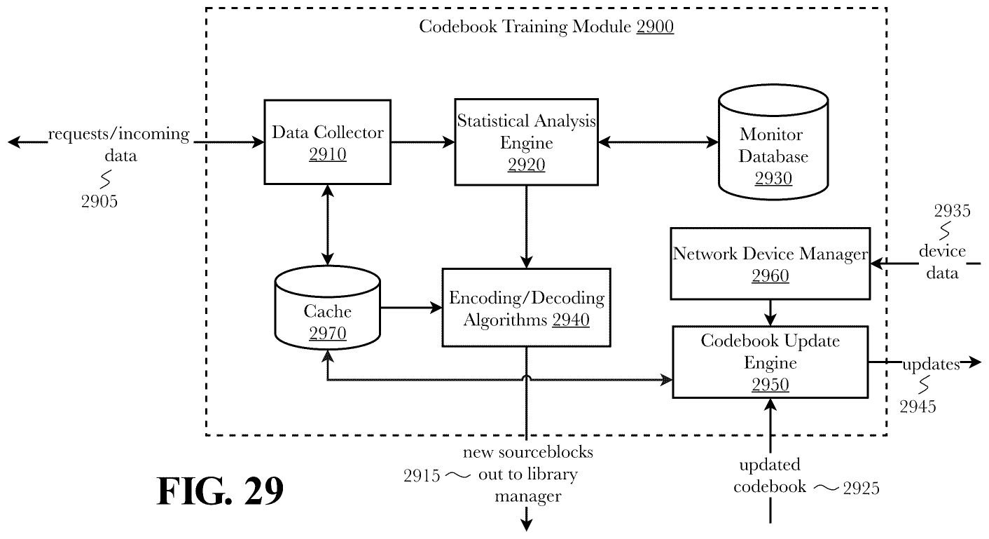

FIG. 29 is a block diagram of an exemplary architecture for a codebook training module 2900, according to an embodiment. According to the embodiment, a data collector 2910 is present which may send requests for incoming data 2905 to a data deconstruction engine 102 which may receive the request and route incoming data to codebook training module 2900 where it may be received by data collector 2910. Data collector 2910 may be configured to request data periodically such as at schedule time intervals, or for example, it may be configured to request data after a certain amount of data has been processed through the encoding machine 2810 or decoding machine 2820. The received data may be a plurality of sourceblocks, which are a series of binary digits, originating from a source packet otherwise referred to as a datagram. The received data may compiled into a test dataset and temporarily stored in a cache 2970. Once stored, the test dataset may be forwarded to a statistical analysis engine 2920 which may utilize one or more algorithms to determine the probability distribution of the test dataset. Best-practice probability distribution algorithms such as Kullback-Leibler divergence, adaptive windowing, and Jensen-Shannon divergence may be used to compute the probability distribution of training and test datasets. A monitoring database 2930 may be used to store a variety of statistical data related to training datasets and model performance metrics in one place to facilitate quick and accurate system monitoring capabilities as well as assist in system debugging functions. For example, the original or current training dataset and the calculated probability distribution of this training dataset used to develop the current encoding and decoding algorithms may be stored in monitor database 2930.

Since data drifts involve statistical change in the data, the best approach to detect drift is by monitoring the incoming data's statistical properties, the model's predictions, and their correlation with other factors. After statistical analysis engine 2920 calculates the probability distribution of the test dataset it may retrieve from monitor database 2930 the calculated and stored probability distribution of the current training dataset. It may then compare the two probability distributions of the two different datasets in order to verify if the difference in calculated distributions exceeds a predetermined difference threshold. If the difference in distributions does not exceed the difference threshold, that indicates the test dataset, and therefore the incoming data, has not experienced enough data drift to cause the encoding/decoding system performance to degrade significantly, which indicates that no updates are necessary to the existing codebooks. However, if the difference threshold has been surpassed, then the data drift is significant enough to cause the encoding/decoding system performance to degrade to the point where the existing models and accompanying codebooks need to be updated. According to an embodiment, an alert may be generated by statistical analysis engine 2920 if the difference threshold is surpassed or if otherwise unexpected behavior arises.

In the event that an update is required, the test dataset stored in the cache 2970 and its associated calculated probability distribution may be sent to monitor database 2930 for long term storage. This test dataset may be used as a new training dataset to retrain the encoding and decoding algorithms 2940 used to create new sourceblocks based upon the changed probability distribution. The new sourceblocks may be sent out to a library manager 2915 where the sourceblocks can be assigned new codewords. Each new sourceblock and its associated codeword may then be added to a new codebook and stored in a storage device. The new and updated codebook may then be sent back 2925 to codebook training module 2900 and received by a codebook update engine 2950. Codebook update engine 2950 may temporarily store the received updated codebook in the cache 2970 until other network devices and machines are ready, at which point codebook update engine 2950 will publish the updated codebooks 2945 to the necessary network devices.

A network device manager 2960 may also be present which may request and receive network device data 2935 from a plurality of network connected devices and machines. When the disclosed encoding system and codebook training system 2800 are deployed in a production environment, upstream process changes may lead to data drift, or other unexpected behavior. For example, a sensor being replaced that changes the units of measurement from inches to centimeters, data quality issues such as a broken sensor always reading zero, and covariate shift which occurs when there is a change in the distribution of input variables from the training set. These sorts of behavior and issues may be determined from the received device data 2935 in order to identify potential causes of system error that is not related to data drift and therefore does not require an updated codebook. This can save network resources from being unnecessarily used on training new algorithms as well as alert system users to malfunctions and unexpected behavior devices connected to their networks. Network device manager 2960 may also utilize device data 2935 to determine available network resources and device downtime or periods of time when device usage is at its lowest. Codebook update engine 2950 may request network and device availability data from network device manager 2960 in order to determine the most optimal time to transmit updated codebooks (i.e., trained libraries) to encoder and decoder devices and machines.

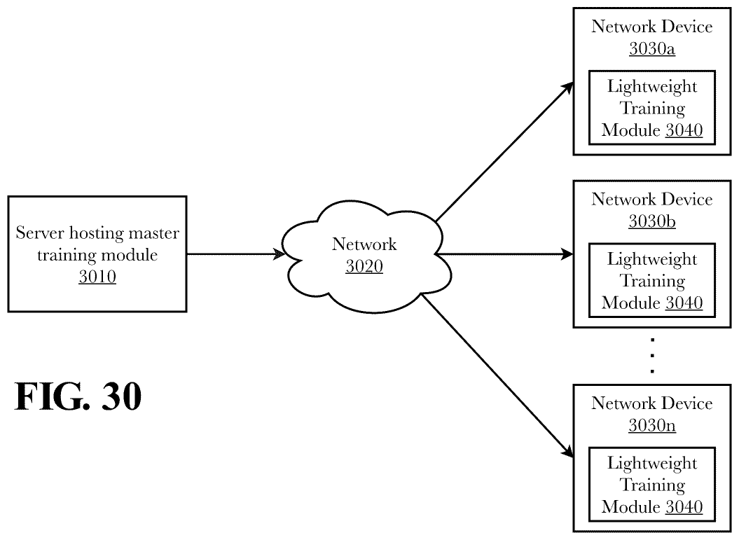

FIG. 30 is a block diagram of another embodiment of the codebook training system using a distributed architecture and a modified training module. According to an embodiment, there may be a server which maintains a master supervisory process over remote training devices hosting a master training module 3010 which communicates via a network 3020 to a plurality of connected network devices 3030a-n. The server may be located at the remote training end such as, but not limited to, cloud-based resources, a user-owned data center, etc. The master training module located on the server operates similarly to the codebook training module disclosed in FIG. 29 above, however, the server 3010 utilizes the master training module via the network device manager 2960 to farm out training resources to network devices 3030a-n. The server 3010 may allocate resources in a variety of ways, for example, round-robin, priority-based, or other manner, depending on the user needs, costs, and number of devices running the encoding/decoding system. Server 3010 may identify elastic resources which can be employed if available to scale up training when the load becomes too burdensome. On the network devices 3030a-n may be present a lightweight version of the training module 3040 that trades a little suboptimality in the codebook for training on limited machinery and/or makes training happen in low-priority threads to take advantage of idle time. In this way the training of new encoding/decoding algorithms may take place in a distributed manner which allows data gathering or generating devices to process and train on data gathered locally, which may improve system latency and optimize available network resources.

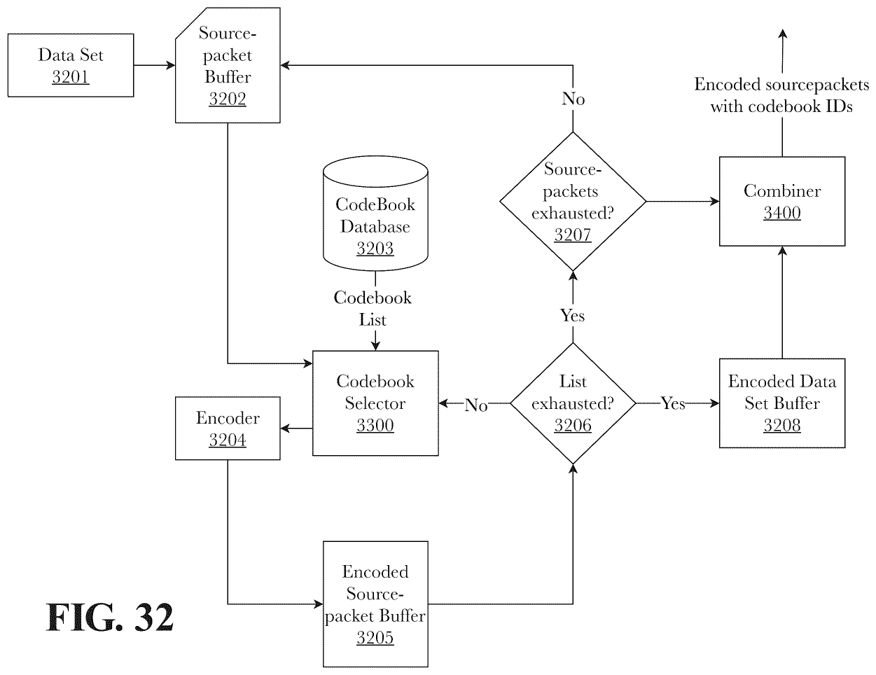

FIG. 32 is an exemplary system architecture for an encoding system with multiple codebooks. A data set to be encoded 3201 is sent to a sourcepacket buffer 3202. The sourcepacket buffer is an array which stores the data which is to be encoded and may contain a plurality of sourcepackets. Each sourcepacket is routed to a codebook selector 3300, which retrieves a list of codebooks from a codebook database 3203. The sourcepacket is encoded using the first codebook on the list via an encoder 3204, and the output is stored in an encoded sourcepacket buffer 3205. The process is repeated with the same sourcepacket using each subsequent codebook on the list until the list of codebooks is exhausted 3206, at which point the most compact encoded version of the sourcepacket is selected from the encoded sourcepacket buffer 3205 and sent to an encoded data set buffer 3208 along with the ID of the codebook used to produce it. The sourcepacket buffer 3202 is determined to be exhausted 3207, a notification is sent to a combiner 3400, which retrieves all of the encoded sourcepackets and codebook IDs from the encoded data set buffer 3208 and combines them into a single file for output.

According to an embodiment, the list of codebooks used in encoding the data set may be consolidated to a single codebook which is provided to the combiner 3400 for output along with the encoded sourcepackets and codebook IDs. In this case, the single codebook will contain the data from, and codebook IDs of, each of the codebooks used to encode the data set. This may provide a reduction in data transfer time, although it is not required since each sourcepacket (or sourceblock) will contain a reference to a specific codebook ID which references a codebook that can be pulled from a database or be sent alongside the encoded data to a receiving device for the decoding process.

In some embodiments, each sourcepacket of a data set 3201 arriving at the encoder 3204 is encoded using a different sourceblock length. Changing the sourceblock length changes the encoding output of a given codebook. Two sourcepackets encoded with the same codebook but using different sourceblock lengths would produce different encoded outputs. Therefore, changing the sourceblock length of some or all sourcepackets in a data set 3201 provides additional security. Even if the codebook was known, the sourceblock length would have to be known or derived for each sourceblock in order to decode the data set 3201. Changing the sourceblock length may be used in conjunction with the use of multiple codebooks.

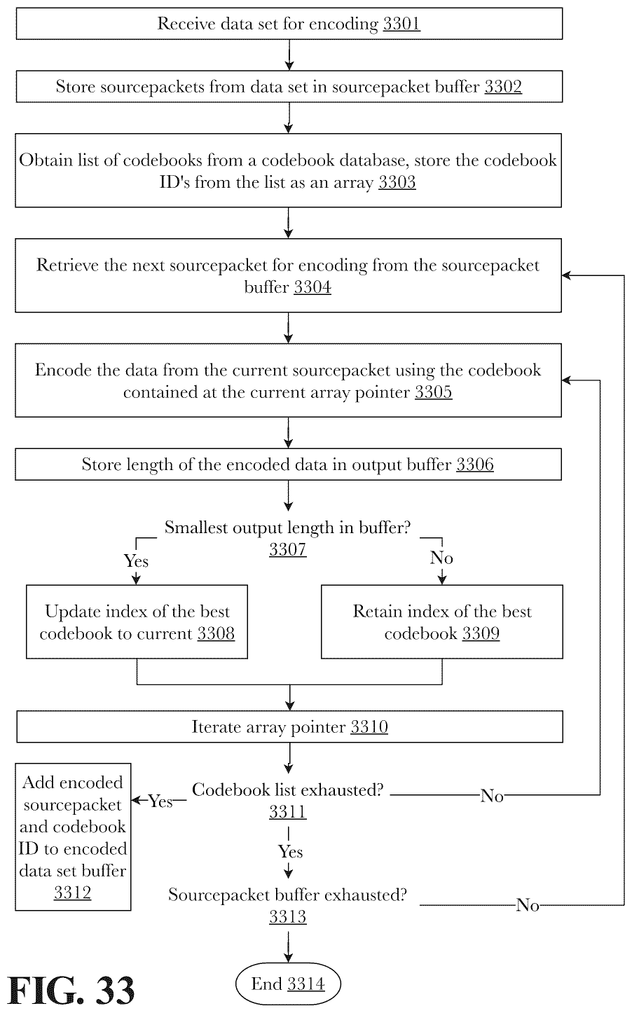

FIG. 33 is a flow diagram describing an exemplary algorithm for encoding of data using multiple codebooks. A data set is received for encoding 3301, the data set comprising a plurality of sourcepackets. The sourcepackets are stored in a sourcepacket buffer 3302. A list of codebooks to be used for multiple codebook encoding is retrieved from a codebook database (which may contain more codebooks than are contained in the list) and the codebook IDs for each codebook on the list are stored as an array 3303. The next sourcepacket in the sourcepacket buffer is retrieved from the sourcepacket buffer for encoding 3304. The sourcepacket is encoded using the codebook in the array indicated by a current array pointer 3305. The encoded sourcepacket and length of the encoded sourcepacket is stored in an encoded sourcepacket buffer 3306. If the length of the most recently stored sourcepacket is the shortest in the buffer 3607, an index in the buffer is updated to indicate that the codebook indicated by the current array pointer is the most efficient codebook in the buffer for that sourcepacket. If the length of the most recently stored sourcepacket is not the shortest in the buffer 3607, the index in the buffer is not updated because a previous codebook used to encode that sourcepacket was more efficient 3309. The current array pointer is iterated to select the next codebook in the list 3310. If the list of codebooks has not been exhausted 3311, the process is repeated for the next codebook in the list, starting at step 3305. If the list of codebooks has been exhausted 3311, the encoded sourcepacket in the encoded sourcepacket buffer (the most compact version) and the codebook ID for the codebook that encoded it are added to an encoded data set buffer 3312 for later combination with other encoded sourcepackets from the same data set. At that point, the sourcepacket buffer is checked to see if any sourcepackets remain to be encoded 3313. If the sourcepacket buffer is not exhausted, the next sourcepacket is retrieved 3304 and the process is repeated starting at step 3304. If the sourcepacket buffer is exhausted 3313, the encoding process ends 3314. In some embodiments, rather than storing the encoded sourcepacket itself in the encoded sourcepacket buffer, a universal unique identification (UUID) is assigned to each encoded sourcepacket, and the UUID is stored in the encoded sourcepacket buffer instead of the entire encoded sourcepacket.

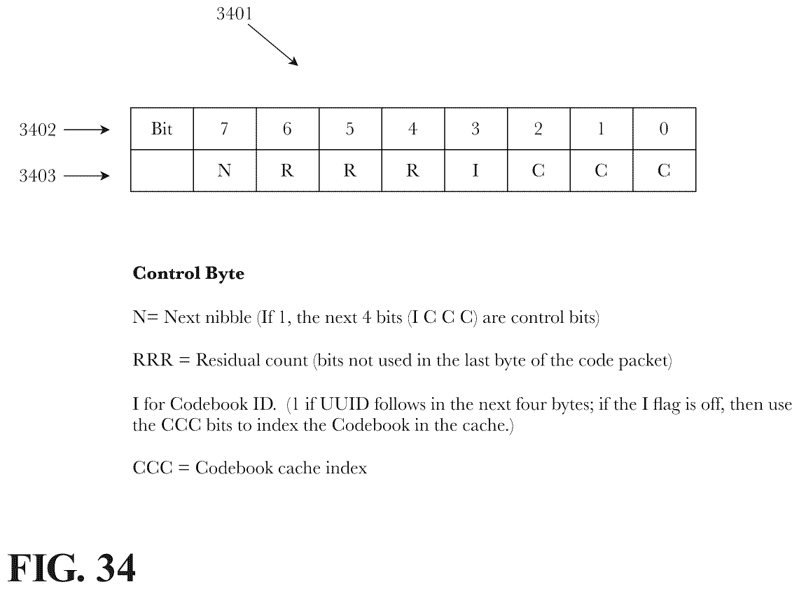

FIG. 34 is a diagram showing an exemplary control byte used to combine sourcepackets encoded with multiple codebooks. In this embodiment, a control byte 3401 (i.e., a series of 8 bits) is inserted at the before (or after, depending on the configuration) the encoded sourcepacket with which it is associated, and provides information about the codebook that was used to encode the sourcepacket. In this way, sourcepackets of a data set encoded using multiple codebooks can be combined into a data structure comprising the encoded sourcepackets, each with a control byte that tells the system how the sourcepacket can be decoded. The data structure may be of numerous forms, but in an embodiment, the data structure comprises a continuous series of control bytes followed by the sourcepacket associated with the control byte. In some embodiments, the data structure will comprise a continuous series of control bytes followed by the UUID of the sourcepacket associated with the control byte (and not the encoded sourcepacket, itself). In some embodiments, the data structure may further comprise a UUID inserted to identify the codebook used to encode the sourcepacket, rather than identifying the codebook in the control byte. Note that, while a very short control code (one byte) is used in this example, the control code may be of any length, and may be considerably longer than one byte in cases where the sourceblocks size is large or in cases where a large number of codebooks have been used to encode the sourcepacket or data set.

In this embodiment, for each bit location 3402 of the control byte 3401, a data bit or combinations of data bits 3403 provide information necessary for decoding of the sourcepacket associated with the control byte. Reading in reverse order of bit locations, the first bit N (location 7) indicates whether the entire control byte is used or not. If a single codebook is used to encode all sourcepackets in the data set, N is set to 0, and bits 3 to 0 of the control byte 3401 are ignored. However, where multiple codebooks are used, N is set to 1 and all 8 bits of the control byte 3401 are used. The next three bits RRR (locations 6 to 4) are a residual count of the number of bits that were not used in the last byte of the sourcepacket. Unused bits in the last byte of a sourcepacket can occur depending on the sourceblock size used to encode the sourcepacket. The next bit I (location 3) is used to identify the codebook used to encode the sourcepacket. If bit I is 0, the next three bits CCC (locations 2 to 0) provide the codebook ID used to encode the sourcepacket. The codebook ID may take the form of a codebook cache index, where the codebooks are stored in an enumerated cache. If bit I is 1, then the codebook is identified using a four-byte UUID that follows the control byte.

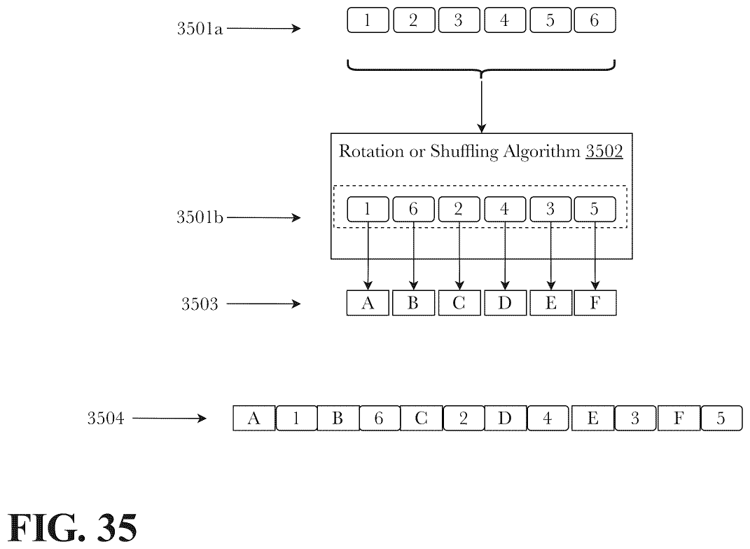

FIG. 35 is a diagram showing an exemplary codebook shuffling method. In this embodiment, rather than selecting codebooks for encoding based on their compaction efficiency, codebooks are selected either based on a rotating list or based on a shuffling algorithm. The methodology of this embodiment provides additional security to compacted data, as the data cannot be decoded without knowing the precise sequence of codebooks used to encode any given sourcepacket or data set.

Here, a list of six codebooks is selected for shuffling, each identified by a number from 1 to 6 3501a. The list of codebooks is sent to a rotation or shuffling algorithm 3502 and reorganized according to the algorithm 3501b. The first six of a series of sourcepackets, each identified by a letter from A to E, 3503 is each encoded by one of the algorithms, in this case A is encoded by codebook 1, B is encoded by codebook 6, C is encoded by codebook 2, D is encoded by codebook 4, E is encoded by codebook 13 A is encoded by codebook 5. The encoded sourcepackets 3503 and their associated codebook identifiers 3501b are combined into a data structure 3504 in which each encoded sourcepacket is followed by the identifier of the codebook used to encode that particular sourcepacket.

According to an embodiment, the codebook rotation or shuffling algorithm 3502 may produce a random or pseudo-random selection of codebooks based on a function. Some non-limiting functions that may be used for shuffling include:
1. given a function f(n) which returns a codebook according to an input parameter n in the range 1 to N are, and given t the number of the current sourcepacket or sourceblock: f(t*M modulo p), where M is an arbitrary multiplying factor (1<=M<=p−1) which acts as a key, and p is a large prime number less than or equal to N;
2. f(A\hat{ }t modulo p), where A is a base relatively prime to p−1 which acts as a key, and p is a large prime number less than or equal to N;
3. f(floor (t*x) modulo N), and x is an irrational number chosen randomly to act as a key;
4. f(t XOR K) where the XOR is performed bit-wise on the binary representations of t and a key K with same number of bits in its representation of N. The function f(n) may return the nth codebook simply by referencing the nth element in a list of codebooks, or it could return the nth codebook given by a formula chosen by a user.

In one embodiment, prior to transmission, the endpoints (users or devices) of a transmission agree in advance about the rotation list or shuffling function to be used, along with any necessary input parameters such as a list order, function code, cryptographic key, or other indicator, depending on the requirements of the type of list or function being used. Once the rotation list or shuffling function is agreed, the endpoints can encode and decode transmissions from one another using the encodings set forth in the current codebook in the rotation or shuffle plus any necessary input parameters.

In some embodiments, the shuffling function may be restricted to permutations within a set of codewords of a given length.

Note that the rotation or shuffling algorithm is not limited to cycling through codebooks in a defined order. In some embodiments, the order may change in each round of encoding. In some embodiments, there may be no restrictions on repetition of the use of codebooks.

In some embodiments, codebooks may be chosen based on some combination of compaction performance and rotation or shuffling. For example, codebook shuffling may be repeatedly applied to each sourcepacket until a codebook is found that meets a minimum level of compaction for that sourcepacket. Thus, codebooks are chosen randomly or pseudo-randomly for each sourcepacket, but only those that produce encodings of the sourcepacket better than a threshold will be used.

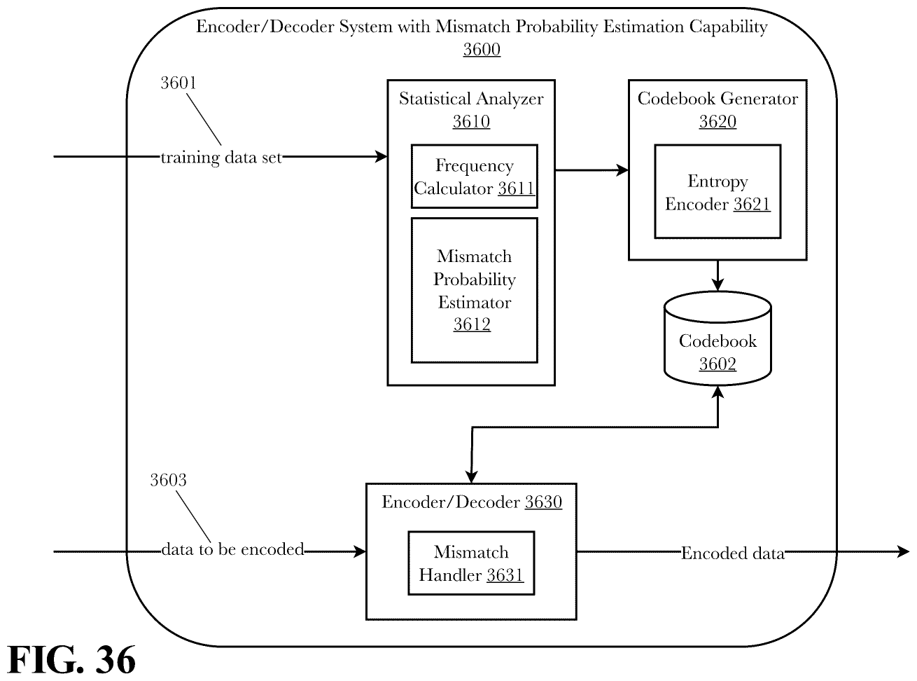

FIG. 36 is a block diagram of an exemplary system architecture for encoding data using mismatch probability estimates, according to an embodiment. According to an embodiment, encoder/decoder system with mismatch probability estimation capability 3600 comprises a statistical analyzer 3610, a codebook generator 3620, a reference codebook 3602, and an encoder/decoder 3630.

Entropy encoding methods (also known as entropy coding methods) are lossless data compression methods which replace fixed-length data inputs with variable-length prefix-free codewords based on the frequency of their occurrence within a given distribution. This reduces the number of bits required to store the data inputs, limited by the entropy of the total data set. The most well-known entropy encoding method is Huffman coding, which will be used in the examples herein.

Because any lossless data compression method must have a code length sufficient to account for the entropy of the data set, entropy encoding is most compact where the entropy of the data set is small. However, smaller entropy in a data set means that, by definition, the data set contains fewer variations of the data. So, the smaller the entropy of a data set used to create a codebook using an entropy encoding method, the larger is the probability that some piece of data to be encoded will not be found in that codebook. Adding new data to the codebook leads to inefficiencies that undermine the use of a low-entropy data set to create the codebook.

System 3600 receives a training data set 3601 comprising one or more sourcepackets of data, wherein each of the one or more sourcepackets of data may further comprise a plurality of sourceblocks. Ideally, training data set 3601 will be selected to closely match data that will later be input into the system for encoding (a low-entropy data set relative to expected data to be encoded). As sourceblocks of training data set data 3601 are processed, statistical analyzer 3610 uses frequency calculator 3611 to keep track of sourceblock frequency, which is the frequency at which each distinct sourceblock occurs in the training data set. Once the training data set 3601 has been fully processed and the sourceblock frequency is known, system 3600 has sufficient information to create a codebook using an entropy encoding method such as Huffman coding. While a codebook can be created at this point, the codebook will not contain codewords for sourceblocks that were either not encountered in the training data sets 3601, or that were included in the training data sets 3601 but were pruned from the codebook for various reasons (as one example, sourceblocks that do not appear frequently enough in a given data set may be pruned for purposes of efficiency or space-saving).

To address the problem of mismatched sourceblocks during encoding (i.e., sourceblocks in data to be encoded which do not have a codeword in the codebook), mismatch probability estimation is used, wherein the probability of encountering data that is not in the codebook is calculated in advance, and a special “mismatch codework” is incorporated into the codebook (the primary encoding algorithm) to represent the expected frequency of encountering previously-unencountered sourceblocks. When a previously-unencountered sourceblock is encountered during encoding, attempting to encode the sourceblock using the codebook results in the mismatch codeword, which triggers a secondary encoding algorithm to encode that sourceblock. The secondary encoding algorithm may result in a less-than-optimal encoding of the previously-unencountered data, but the efficiencies of using a low-entropy primary encoding make up for the inefficiencies of the secondary encoding algorithm. Because the use of the secondary encoding algorithm has been accounted for in the codebook (the primary encoding algorithm) by the mismatch probability estimation, the overall efficiency of compaction is improved over other entropy encoding methods.

Mismatch probability estimator 3612 calculates the probability that a sourceblock to be encoded will not be in the codebook generated from the training data. This probability is difficult to estimate because it is the probability that a sourceblock is not one which was seen in the training data (i.e., the system needs to estimate the probability of a previously-unseen event). Several algorithms for calculating the mismatch probability follow. The mismatch probability in these algorithms is defined as q. These algorithms are intended to be exemplary, and not exclusive of other algorithms that could be used to calculate this probability.

In a first algorithm, q is taken to be the number M of times a mismatch occurred during training (i.e., when a previous-unobserved sourceblock appeared in the training data), dividing by the total number N of sourceblocks observed during training, i.e., q=M/N. However, for many training data sets, a static q=M/N may not be an accurate estimate for q, as the mismatch frequency may fall with time as training data is ingested, resulting in a q that is too high. This is likely to be the case where the training and real-world data are drawn from the same data type.

A second algorithm that improves on the first uses a sum of probabilities to calculate q. Suppose that sourceblocks S₁, S₂, . . . , S_{N} are observed during training. For j=1, . . . , N, let the variable Xⱼ denote the indicator of the event that sourceblock Sⱼ is a mismatch, i.e.,

$${X}_{j} = \{ \begin{matrix}1 & if {S}_{j} ∉ \{ {S}_{i} : 1 \leq i < j \} \\ 0 & otherwise\end{matrix}$$

Then we can write

$$q = M / N = ( {\sum }_{j = 1}^{N} {X}_{j} ) / N .$$

A third algorithm that improves on the second, employs a modified exponentially-weighted moving average (EWMA) to calculate changes in q over time:

$${μ}_{j} = \{ \begin{matrix}1 & if j = 0 \\ ( 1 - {β}_{j} ) {μ}_{j - 1} + {β}_{j} {X}_{j} & if j > 0\end{matrix} \begin{matrix} \\ \end{matrix}$$

If βⱼ, a quantity between 0 and 1, were constant (i.e., not depending on j), then this is a classical EWMA. However, there are two issues to balance in choosing βⱼ: a value too close to 1 causes extreme volatility in the estimate μⱼ, since it will depend only on very recent occurrences/nonoccurrences of mismatches; and a value too close to 0 will cause difficult round-off errors or else cause the estimate to depend on very early training data (when mismatch frequencies will be misleadingly high). Therefore, we take βⱼ=C log(j)/j (and β₁=1 to avoid initialization problems), for some constant C. In practice, we have observed C=1 to be a good choice here, though it is by no means the only possibility, and some applications with particularly stable or unstable mismatch distributions will benefit from a different value. The effect of this choice is to cause the mismatch probability estimate μⱼ to depend only on the recent O(1/log (j)) fraction of the data when sourceblock j is observed, a quantity tending to zero slowly.

Two additional adjustments may be made to deal with certain cases. First, when training begins, the statistic μⱼ is highly volatile, resulting in poor estimates if the training data is very small. Therefore, an adjustment to the algorithm for this case is to monitor the sample standard deviation σⱼ of μⱼ and use the aforementioned M/N estimate until σⱼ falls below some pre-set tolerance, for example the condition that σⱼ/μⱼ<10%. This value of 10% can be replaced with another value if experimentation shows that a difference value is warranted for a particular data type. Second, the quantity μⱼ tends to be a slight overestimate because it will fall over time during training, so it may be biased slightly above the true mismatch probability. Therefore, am adjustment to the algorithm for this case is to use the smallest recent value of μⱼ instead of μⱼ itself, i.e.,

$${μ}_{j}^{′} = {min}_{j - B \leq i \leq j} {μ}_{i}$$

where B is a “windowing” parameter reflecting how far back in the history of the training process to incorporate in the estimate, and negative indices are ignored. It may be useful in some circumstances to take a variable value for B=Bⱼ instead of a constant, a reasonable choice being Bⱼ=j/(C log j), the effective window size for the EWMA discussed above.

After the mismatch probability estimate is made, codebook generator 3620 generates a codebook using entropy encoder 3621. Entropy encoder 3621 uses an entropy encoding method to create a codebook based on the frequency of occurrences of each sourceblock in the training data set, including the estimated frequency of occurrence of mismatched sourceblocks, for which a special “mismatch codeword” is inserted into the codebook. The resulting codebook is stored in a database 3602, which is accessed by encoder/decoder 3630 to encode data to be encoded 3603. When a mismatch occurs and the mismatch codeword is returned, mismatch handler 3631 receives the mismatched sourceblock and encodes it using a secondary encoding method, inserting the secondary encoding into the encoded data stream and returning the encoding process to encoding using the codebook (the primary encoding method).

### Detailed Description of Exemplary Aspects

Since the library consists of re-usable building sourceblocks, and the actual data is represented by reference codes to the library, the total storage space of a single set of data would be much smaller than conventional methods, wherein the data is stored in its entirety. The more data sets that are stored, the larger the library becomes, and the more data can be stored in reference code form.

As an analogy, imagine each data set as a collection of printed books that are only occasionally accessed. The amount of physical shelf space required to store many collections would be quite large and is analogous to conventional methods of storing every single bit of data in every data set. Consider, however, storing all common elements within and across books in a single library, and storing the books as references codes to those common elements in that library. As a single book is added to the library, it will contain many repetitions of words and phrases. Instead of storing the whole words and phrases, they are added to a library, and given a reference code, and stored as reference codes. At this scale, some space savings may be achieved, but the reference codes will be on the order of the same size as the words themselves. As more books are added to the library, larger phrases, quotations, and other words patterns will become common among the books. The larger the word patterns, the smaller the reference codes will be in relation to them as not all possible word patterns will be used. As entire collections of books are added to the library, sentences, paragraphs, pages, or even whole books will become repetitive. There may be many duplicates of books within a collection and across multiple collections, many references and quotations from one book to another, and much common phraseology within books on particular subjects. If each unique page of a book is stored only once in a common library and given a reference code, then a book of 1,000 pages or more could be stored on a few printed pages as a string of codes referencing the proper full-sized pages in the common library. The physical space taken up by the books would be dramatically reduced. The more collections that are added, the greater the likelihood that phrases, paragraphs, pages, or entire books will already be in the library, and the more information in each collection of books can be stored in reference form. Accessing entire collections of books is then limited not by physical shelf space, but by the ability to reprint and recycle the books as needed for use.

The projected increase in storage capacity using the method herein described is primarily dependent on two factors: 1) the ratio of the number of bits in a block to the number of bits in the reference code, and 2) the amount of repetition in data being stored by the system.

With respect to the first factor, the number of bits used in the reference codes to the sourceblocks must be smaller than the number of bits in the sourceblocks themselves in order for any additional data storage capacity to be obtained. As a simple example, 16-bit sourceblocks would require 2¹⁶, or 65536, unique reference codes to represent all possible patterns of bits. If all possible 65536 blocks patterns are utilized, then the reference code itself would also need to contain sixteen bits in order to refer to all possible 65,536 blocks patterns. In such case, there would be no storage savings. However, if only 16 of those block patterns are utilized, the reference code can be reduced to 4 bits in size, representing an effective compression of 4 times (16 bits/4 bits=4) versus conventional storage. Using a typical block size of 512 bytes, or 4,096 bits, the number of possible block patterns is 24.096, which for all practical purposes is unlimited. A typical hard drive contains one terabyte (TB) of physical storage capacity, which represents 1,953,125,000, or roughly 2³¹, 512 byte blocks. Assuming that 1 TB of unique 512-byte sourceblocks were contained in the library, and that the reference code would thus need to be 31 bits long, the effective compression ratio for stored data would be on the order of 132 times (4,096/31≈132) that of conventional storage.

With respect to the second factor, in most cases it could be assumed that there would be sufficient repetition within a data set such that, when the data set is broken down into sourceblocks, its size within the library would be smaller than the original data. However, it is conceivable that the initial copy of a data set could require somewhat more storage space than the data stored in a conventional manner, if all or nearly all sourceblocks in that set were unique. For example, assuming that the reference codes are 1/10^{th} the size of a full-sized copy, the first copy stored as sourceblocks in the library would need to be 1.1 megabytes (MB), (1 MB for the complete set of full-sized sourceblocks in the library and 0.1 MB for the reference codes). However, since the sourceblocks stored in the library are universal, the more duplicate copies of something you save, the greater efficiency versus conventional storage methods. Conventionally, storing 10 copies of the same data requires 10 times the storage space of a single copy. For example, ten copies of a 1 MB file would take up 10 MB of storage space. However, using the method described herein, only a single full-sized copy is stored, and subsequent copies are stored as reference codes. Each additional copy takes up only a fraction of the space of the full-sized copy. For example, again assuming that the reference codes are 1/10^{th} the size of the full-size copy, ten copies of a 1 MB file would take up only 2 MB of space (1 MB for the full-sized copy, and 0.1 MB each for ten sets of reference codes). The larger the library, the more likely that part or all of incoming data will duplicate sourceblocks already existing in the library.

The size of the library could be reduced in a manner similar to storage of data. Where sourceblocks differ from each other only by a certain number of bits, instead of storing a new sourceblock that is very similar to one already existing in the library, the new sourceblock could be represented as a reference code to the existing sourceblock, plus information about which bits in the new block differ from the existing block. For example, in the case where 512 byte sourceblocks are being used, if the system receives a new sourceblock that differs by only one bit from a sourceblock already existing in the library, instead of storing a new 512 byte sourceblock, the new sourceblock could be stored as a reference code to the existing sourceblock, plus a reference to the bit that differs. Storing the new sourceblock as a reference code plus changes would require only a few bytes of physical storage space versus the 512 bytes that a full sourceblock would require. The algorithm could be optimized to store new sourceblocks in this reference code plus changes form unless the changes portion is large enough that it is more efficient to store a new, full sourceblock.

It will be understood by one skilled in the art that transfer and synchronization of data would be increased to the same extent as for storage. By transferring or synchronizing reference codes instead of full-sized data, the bandwidth requirements for both types of operations are dramatically reduced.

In addition, the method described herein is inherently a form of encryption. When the data is converted from its full form to reference codes, none of the original data is contained in the reference codes. Without access to the library of sourceblocks, it would be impossible to reconstruct any portion of the data from the reference codes. This inherent property of the method described herein could obviate the need for traditional encryption algorithms, thereby offsetting most or all of the computational cost of conversion of data back and forth to reference codes. In theory, the method described herein should not utilize any additional computing power beyond traditional storage using encryption algorithms. Alternatively, the method described herein could be in addition to other encryption algorithms to increase data security even further.

In other embodiments, additional security features could be added, such as: creating a proprietary library of sourceblocks for proprietary networks, physical separation of the reference codes from the library of sourceblocks, storage of the library of sourceblocks on a removable device to enable easy physical separation of the library and reference codes from any network, and incorporation of proprietary sequences of how sourceblocks are read and the data reassembled.

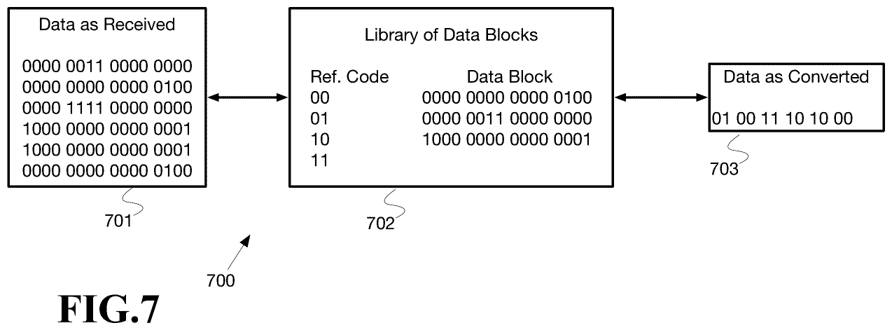

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11 is initially empty. As each 16 bit sourceblock is received, it is compared with the library. If that sourceblock is already contained in the library, it is assigned the corresponding reference code. So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

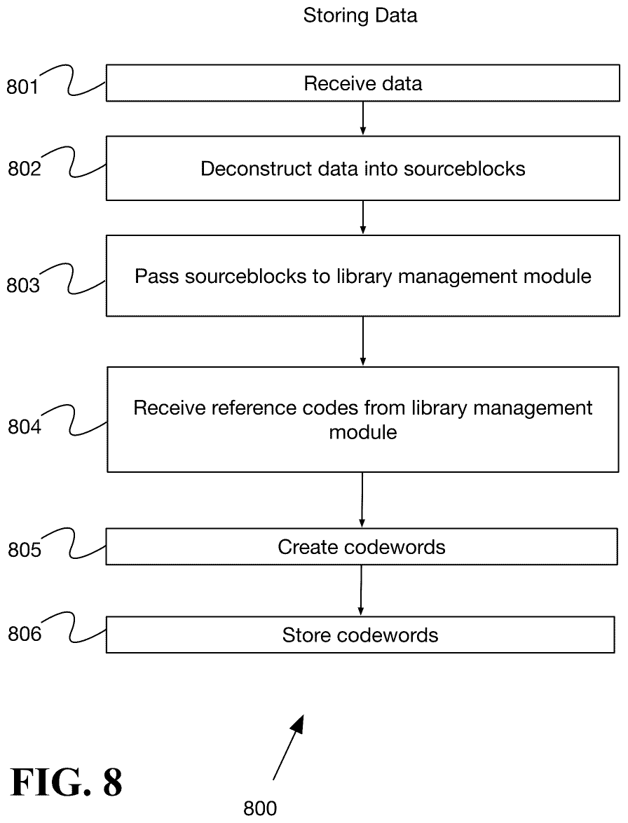

FIG. 8 is a method diagram showing the steps involved in using an embodiment 800 to store data. As data is received 801, it would be deconstructed into sourceblocks 802, and passed 803 to the library management module for processing. Reference codes would be received back 804 from the library management module and could be combined with location information to create codewords 805, which would then be stored 806 as representations of the original data.

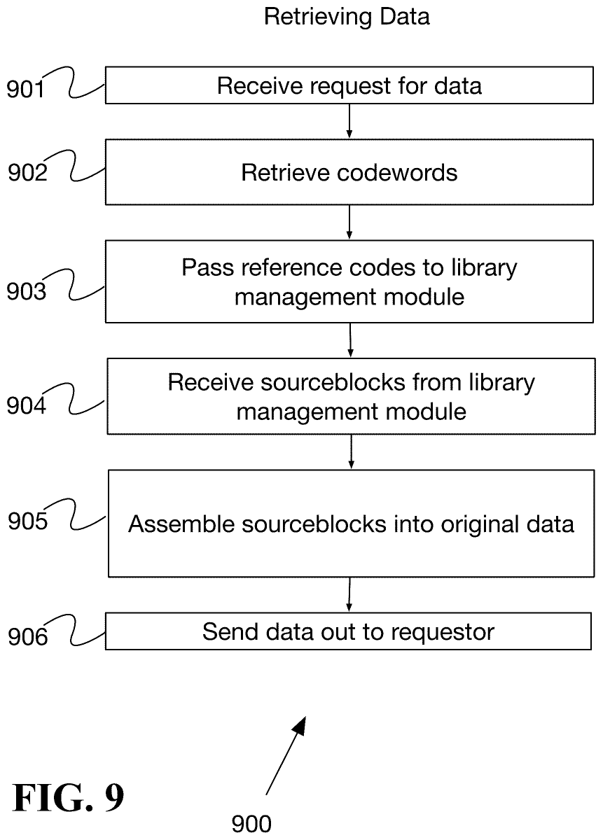

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

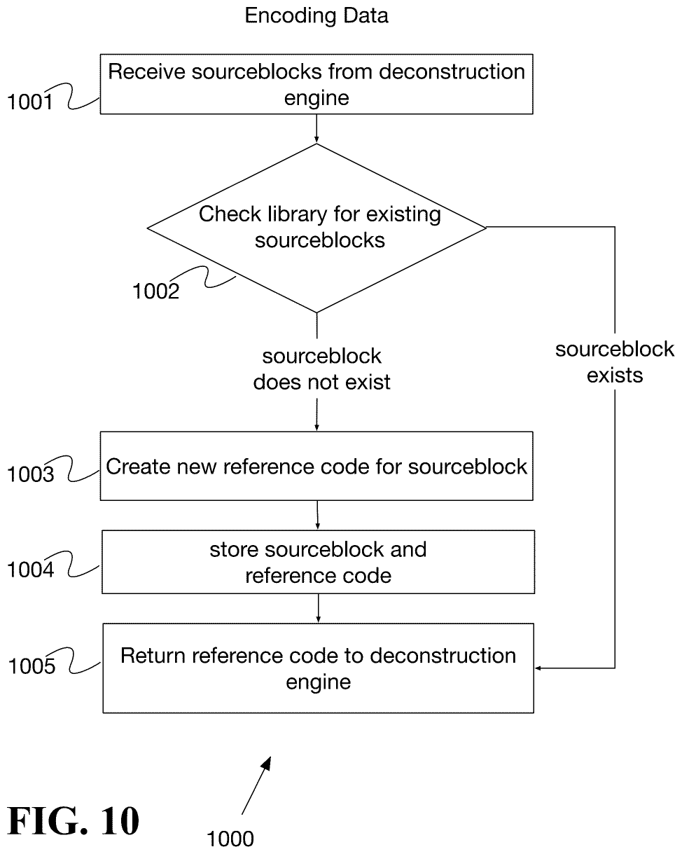

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

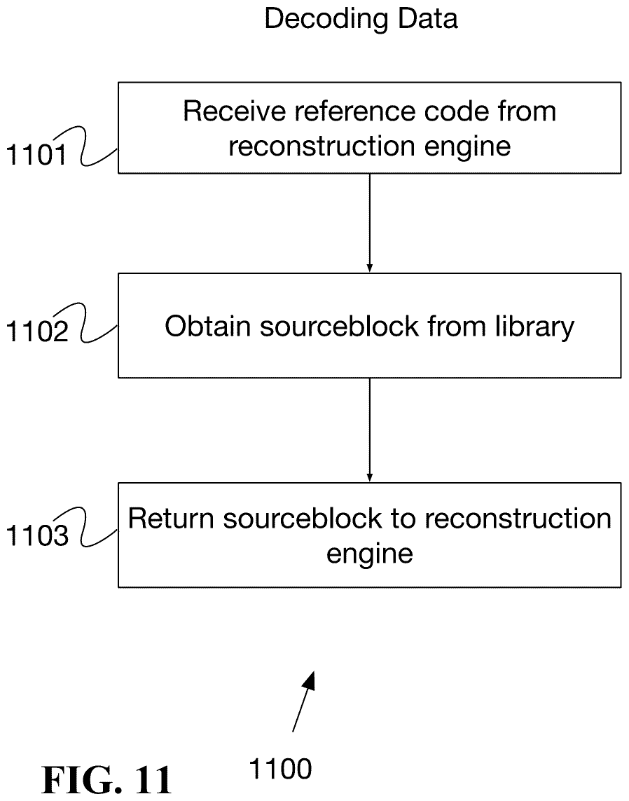

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

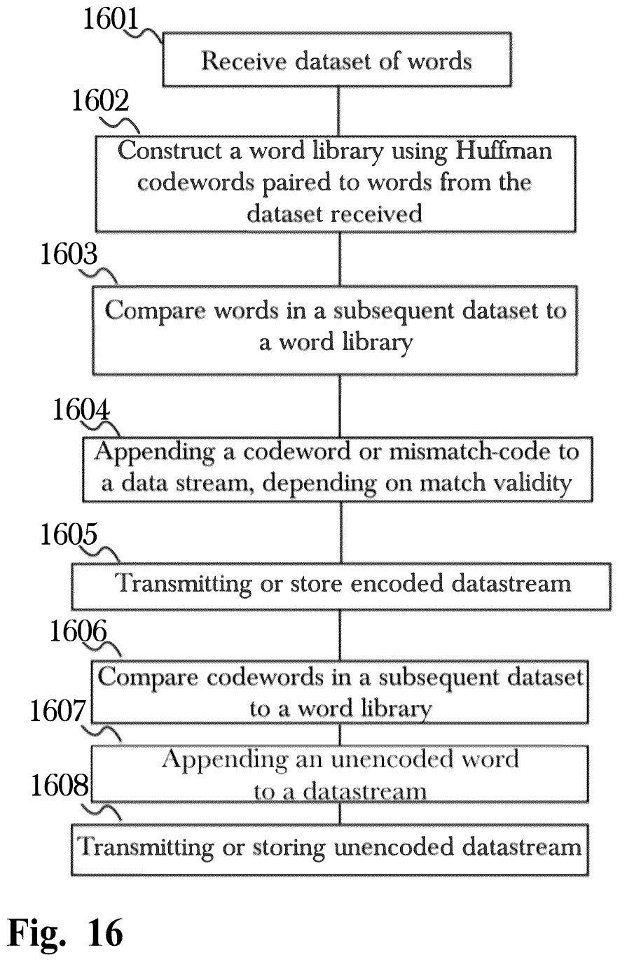

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received and compared to the word library 1603 to determine the proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

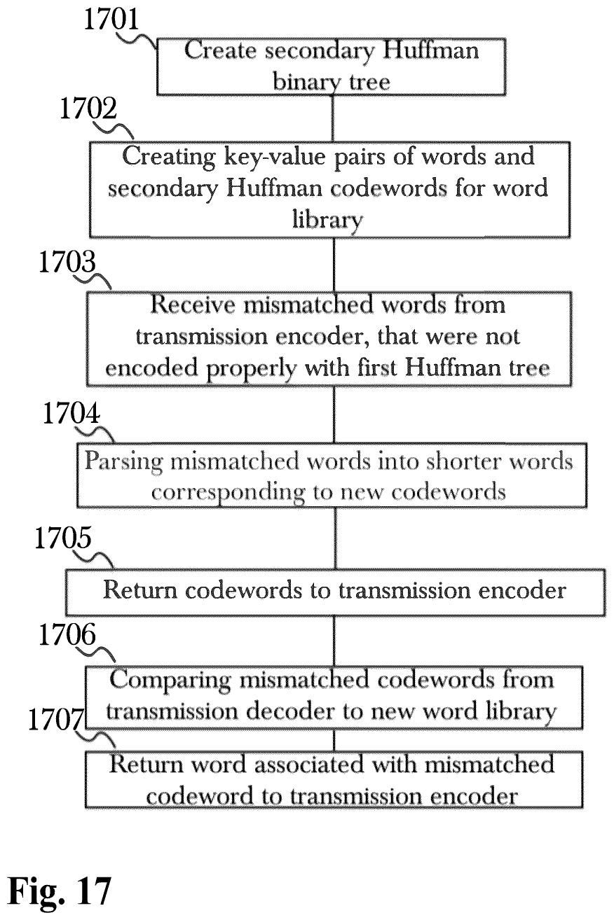

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

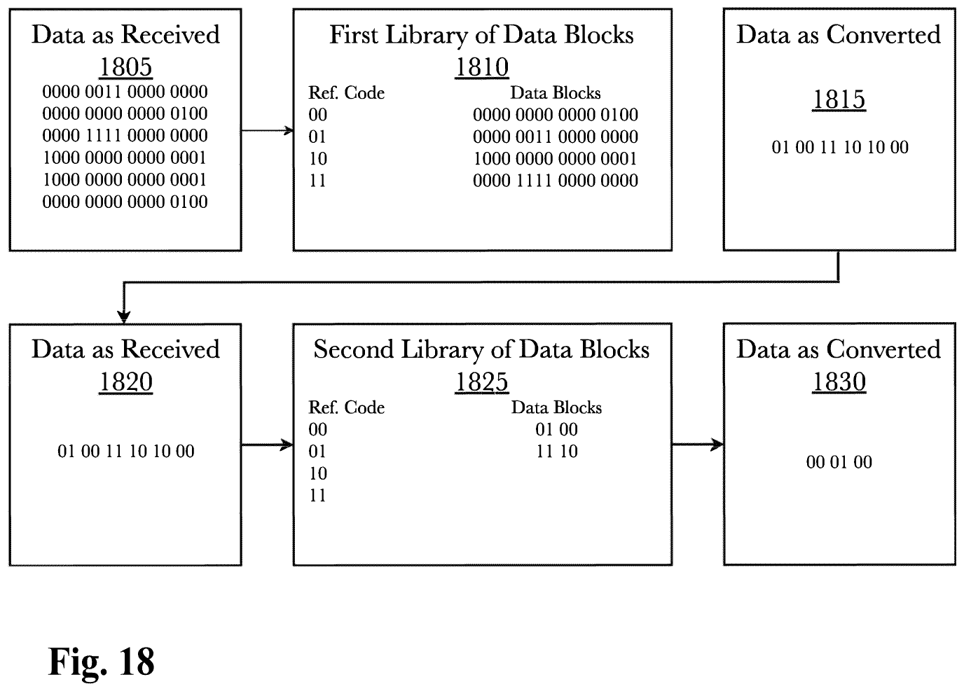

FIG. 18 is a flow diagram illustrating the use of a data encoding system used to recursively encode data to further reduce data size. Data may be input 1805 into a data deconstruction engine 102 to be deconstructed into code references, using a library of code references based on the input 1810. Such example data is shown in a converted, encoded format 1815, highly compressed, reducing the example data from 96 bits of data, to 12 bits of data, before sending this newly encoded data through the process again 1820, to be encoded by a second library 1825, reducing it even further. The newly converted data 1830 is shown as only 6 bits in this example, thus a size of 6.25% of the original data packet. With recursive encoding, then, it is possible and implemented in the system to achieve increasing compression ratios, using multi-layered encoding, through recursively encoding data. Both initial encoding libraries 1810 and subsequent libraries 1825 may be achieved through machine learning techniques to find optimal encoding patterns to reduce size, with the libraries being distributed to recipients prior to transfer of the actual encoded data, such that only the compressed data 1830 must be transferred or stored, allowing for smaller data footprints and bandwidth requirements. This process can be reversed to reconstruct the data. While this example shows only two levels of encoding, recursive encoding may be repeated any number of times. The number of levels of recursive encoding will depend on many factors, a non-exhaustive list of which includes the type of data being encoded, the size of the original data, the intended usage of the data, the number of instances of data being stored, and available storage space for codebooks and libraries. Additionally, recursive encoding can be applied not only to data to be stored or transmitted, but also to the codebooks and/or libraries, themselves. For example, many installations of different libraries could take up a substantial amount of storage space. Recursively encoding those different libraries to a single, universal library would dramatically reduce the amount of storage space required, and each different library could be reconstructed as necessary to reconstruct incoming streams of data.

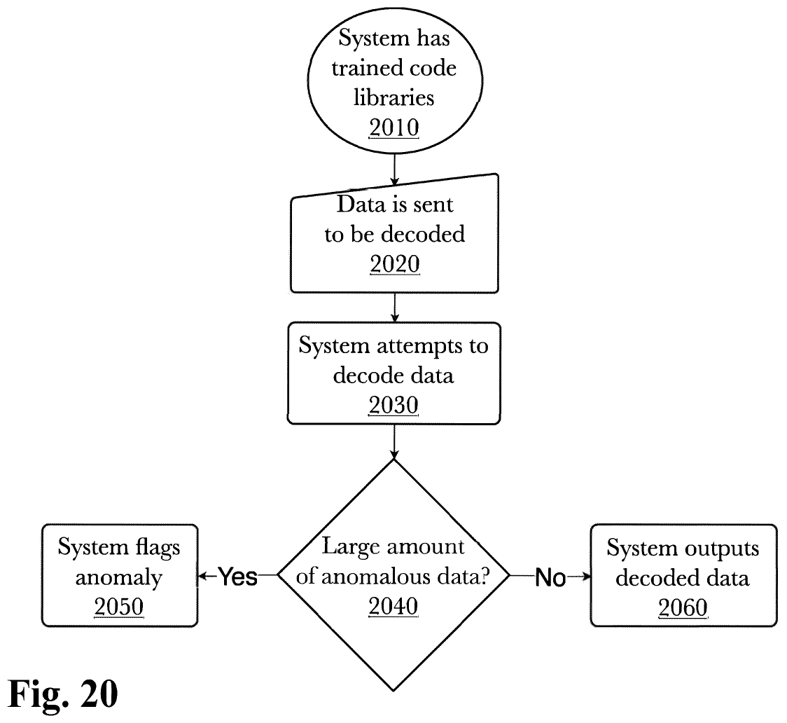

FIG. 20 is a flow diagram of an exemplary method used to detect anomalies in received encoded data and producing a warning. A system may have trained encoding libraries 2010, before data is received from some source such as a network connected device or a locally connected device including USB connected devices, to be decoded 2020. Decoding in this context refers to the process of using the encoding libraries to take the received data and attempt to use encoded references to decode the data into its original source 2030, potentially more than once if recursive encoding was used, but not necessarily more than once. An anomaly detector 1910 may be configured to detect a large amount of un-encoded data 2040 in the midst of encoded data, by locating data or references that do not appear in the encoding libraries, indicating at least an anomaly, and potentially data tampering or faulty encoding libraries. A flag or warning is set by the system 2050, allowing a user to be warned at least of the presence of the anomaly and the characteristics of the anomaly. However, if a large amount of invalid references or unencoded data are not present in the encoded data that is attempting to be decoded, the data may be decoded and output as normal 2060, indicating no anomaly has been detected.

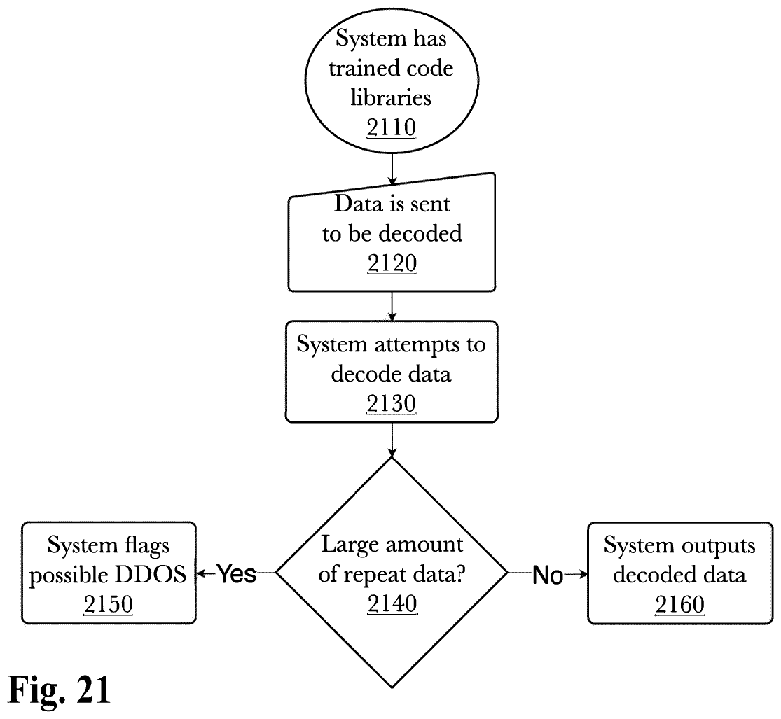

FIG. 21 is a flow diagram of a method used for Distributed Denial of Service (DDoS) attack denial. A system may have trained encoding libraries 2110, before data is received from some source such as a network connected device or a locally connected device including USB connected devices, to be decoded 2120. Decoding in this context refers to the process of using the encoding libraries to take the received data and attempt to use encoded references to decode the data into its original source 2130, potentially more than once if recursive encoding was used, but not necessarily more than once. A DDoS detector 1920 may be configured to detect a large amount of repeating data 2140 in the encoded data, by locating data or references that repeat many times over (the number of which can be configured by a user or administrator as need be), indicating a possible DDoS attack. A flag or warning is set by the system 2150, allowing a user to be warned at least of the presence of a possible DDoS attack, including characteristics about the data and source that initiated the flag, allowing a user to then block incoming data from that source. However, if a large amount of repeat data in a short span of time is not detected, the data may be decoded and output as normal 2160, indicating no DDoS attack has been detected.

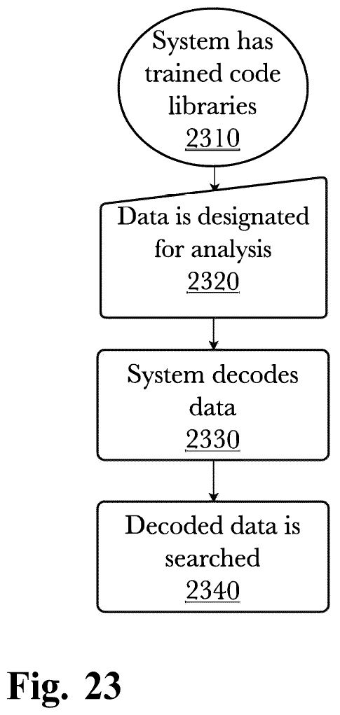

FIG. 23 is a flow diagram of an exemplary method used to enable high-speed data mining of repetitive data. A system may have trained encoding libraries 2310, before data is received from some source such as a network connected device or a locally connected device including USB connected devices, to be analyzed 2320 and decoded 2330. When determining data for analysis, users may select specific data to designate for decoding 2330, before running any data mining or analytics functions or software on the decoded data 2340. Rather than having traditional decryption and decompression operate over distributed drives, data can be regenerated immediately using the encoding libraries disclosed herein, as it is being searched. Using methods described in FIG. 9 and FIG. 11, data can be stored, retrieved, and decoded swiftly for searching, even across multiple devices, because the encoding library may be on each device. For example, if a group of servers host codewords relevant for data mining purposes, a single computer can request these codewords, and the codewords can be sent to the recipient swiftly over the bandwidth of their connection, allowing the recipient to locally decode the data for immediate evaluation and searching, rather than running slow, traditional decompression algorithms on data stored across multiple devices or transfer larger sums of data across limited bandwidth.

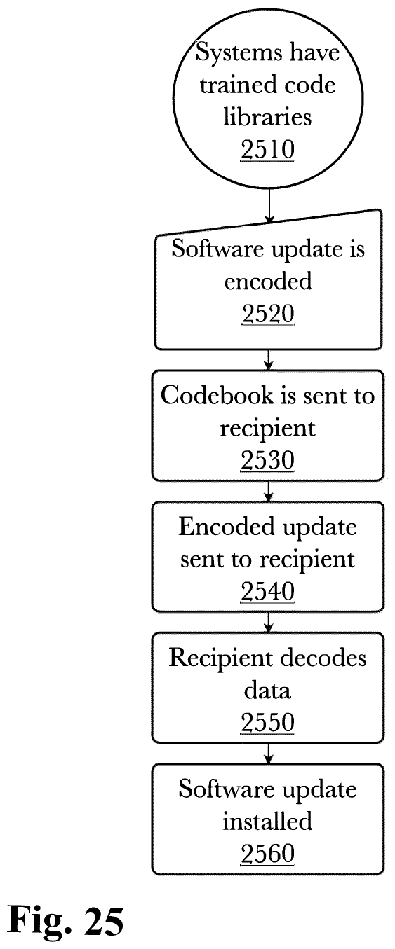

FIG. 25 is a flow diagram of an exemplary method used to encode and transfer software and firmware updates to a device for installation, for the purposes of reduced bandwidth consumption. A first system may have trained code libraries or “codebooks” present 2510, allowing for a software update of some manner to be encoded 2520. Such a software update may be a firmware update, operating system update, security patch, application patch or upgrade, or any other type of software update, patch, modification, or upgrade, affecting any computer system. A codebook for the patch must be distributed to a recipient 2530, which may be done beforehand and either over a network or through a local or physical connection, but must be accomplished at some point in the process before the update may be installed on the recipient device 2560. An update may then be distributed to a recipient device 2540, allowing a recipient with a codebook distributed to them 2530 to decode the update 2550 before installation 2560. In this way, an encoded and thus heavily compressed update may be sent to a recipient far quicker and with less bandwidth usage than traditional lossless compression methods for data, or when sending data in uncompressed formats. This especially may benefit large distributions of software and software updates, as with enterprises updating large numbers of devices at once.

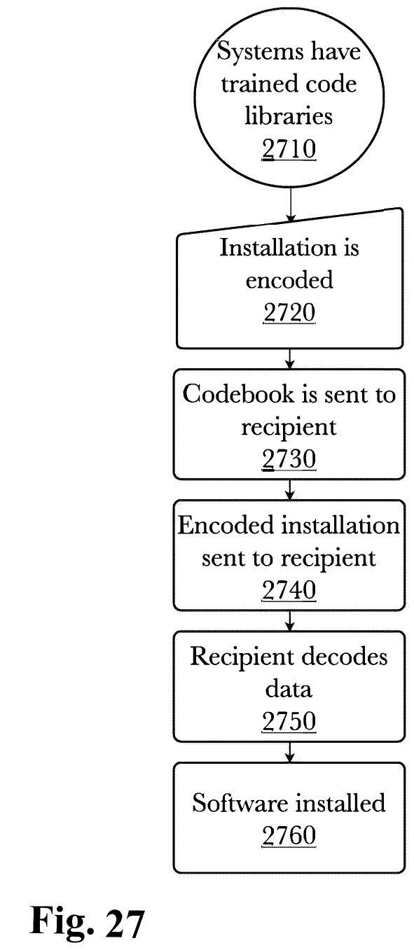

FIG. 27 is a flow diagram of an exemplary method used to encode new software and operating system installations for reduced bandwidth required for transference. A first system may have trained code libraries or “codebooks” present 2710, allowing for a software installation of some manner to be encoded 2720. Such a software installation may be a software update, operating system, security system, application, or any other type of software installation, execution, or acquisition, affecting a computer system. An encoding library or “codebook” for the installation must be distributed to a recipient 2730, which may be done beforehand and either over a network or through a local or physical connection but must be accomplished at some point in the process before the installation can begin on the recipient device 2760. An installation may then be distributed to a recipient device 2740, allowing a recipient with a codebook distributed to them 2730 to decode the installation 2750 before executing the installation 2760. In this way, an encoded and thus heavily compressed software installation may be sent to a recipient far quicker and with less bandwidth usage than traditional lossless compression methods for data, or when sending data in uncompressed formats. This especially may benefit large distributions of software and software updates, as with enterprises updating large numbers of devices at once.

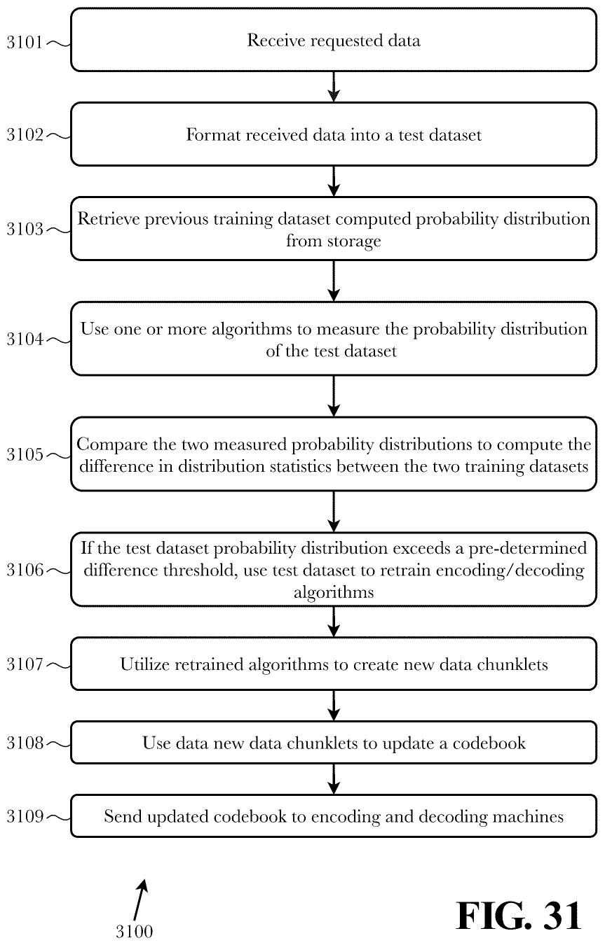

FIG. 31 is a method diagram illustrating the steps 3100 involved in using an embodiment of the codebook training system to update a codebook. The process begins when requested data is received 3101 by a codebook training module. The requested data may comprise a plurality of sourceblocks. Next, the received data may be stored in a cache and formatted into a test dataset 3102. The next step is to retrieve the previously computed probability distribution associated with the previous (most recent) training dataset from a storage device 3103. Using one or more algorithms, measure and record the probability distribution of the test dataset 3104. The step after that is to compare the measured probability distributions of the test dataset and the previous training dataset to compute the difference in distribution statistics between the two datasets 3105. If the test dataset probability distribution exceeds a pre-determined difference threshold, then the test dataset will be used to retrain the encoding/decoding algorithms 3106 to reflect the new distribution of the incoming data to the encoder/decoder system. The retrained algorithms may then be used to create new data sourceblocks 3107 that better capture the nature of the data being received. These newly created data sourceblocks may then be used to create new codewords and update a codebook 3108 with each new data sourceblock and its associated new codeword. Last, the updated codebooks may be sent to encoding and decoding machines 3109 in order to ensure the encoding/decoding system function properly.

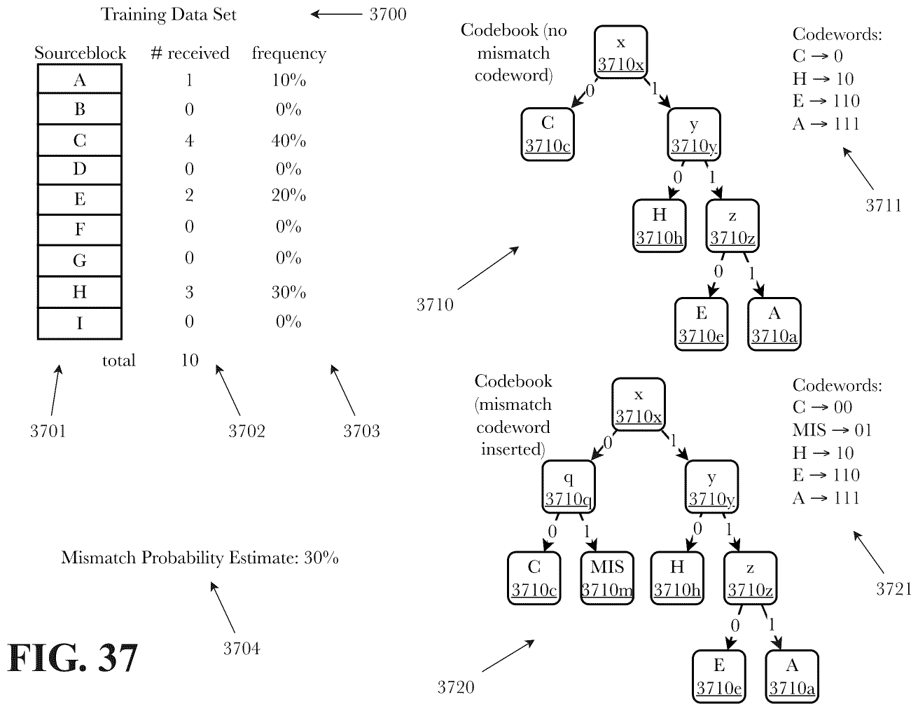

FIG. 37 is a diagram illustrating an exemplary method for codebook generation from a training data set. In this simplified example, a training data set 3700 comprised of nine different potential types of sourceblocks 3701 is received. The number of sourceblocks actually received is 10, one of sourceblock A, four of sourceblock C, two of sourceblock E, and three of sourceblock H. This is a low-entropy data set in that the types of sourceblocks actually received are highly regular (lots of A, C, E, and H, and none of B, D, F, G, and I). None of the other types of sourceblocks are received. The frequency of occurrence of each sourceblock, therefore, is 10% A, 40% C, 20% E, and 30% H. Using these frequencies of occurrence, a codebook could be created with no mismatch codeword as shown in the codebook 3710 represented by a Huffman binary tree having three empty nodes, x 3710x, y 3710y, and z 3710z, leading to leaf nodes for sourceblocks C 3710c, H 3710h, E 3710e, and A 3710a, according to their frequencies of occurrence in training data set 3700. This codebook 3710 represents codewords for sourceblocks C, H, E, and A as follows: C→0, H→10, E→110, and A→111 by following the appropriate paths of the codebook 3710. However, this codebook does not account for the relatively high probability of occurrence of mismatches during encoding if sourceblocks B, D, F, G, and I appear in the data to be encoded. If this codebook 3710 is used, sourceblocks B, D, F, G, and I could not be encoded. If a Huffman binary tree was created to include sourceblocks B, D, F, G, and I, each of them would be assigned increasingly inefficient leaf nodes after the lowest probability leaf node in the tree, A 3710a. For example, if B was assigned after A 3701a, its codeword would be 1110, followed by D with a codeword of 11110, and so on.

To address this problem of inability to assign codewords or inefficiency in assigning codewords using a low-entropy training data set, a codebook 3720 can be created with a mismatch codeword MIS 3710m inserted representing the probability of mismatch during encoding. If the mismatch probability estimate 3704 is 30% (equivalent in probability to receiving sourceblock H), for example, the resulting codebook 3720 would include an additional empty node q 3710q leading to leaf node MIS 3710m, at a roughly equivalent level of probability (and corresponding short codeword) as sourceblock C 3710c and sourceblock H 3710h. This codebook 3720 represents codewords for sourceblocks C, MIS, H, E, and A as follows: C→00, MIS→01, H→10, E→110, and A→111 by following the appropriate paths of the codebook 3720. Unlike codebook 3710, however, codebook 3720 is capable of coding for any arbitrary mismatch sourcblock received, including but not limited to sourceblocks B, D, F, G, and I. During encoding, a codework result of 01 (MIS) triggers a secondary encoding method for the mismatched sourceblock. A variety of secondary encoding methods may be used including, but not limited to no encoding (i.e., using the sourceblock as received) or using a suboptimal but guaranteed-to-work entropy encoding method that uses a shorter block-length for encoding.

While this example uses a single mismatch codeword, in other embodiments, multiple mismatch codewords may be used, signaling, for example, different probabilities of mismatches for different types of sourceblocks. Further, while this example uses a single secondary encoding method, other embodiments may use a plurality of such secondary methods, or additional levels of encoding methods (tertiary, quaternary, etc.). Multiple mismatch codewords may be associated with the plurality of secondary methods and/or additional levels of encoding methods.

Decoding of data compacted using this method is the reverse of the encoding process. A stream of codewords are received. Any codewords from the codebook (the primary encoding) are looked up in the codebook to retrieve their associated sourceblocks. Any codewords from secondary encoding are looked up using the secondary encoding method to retrieve their associated sourceblocks.

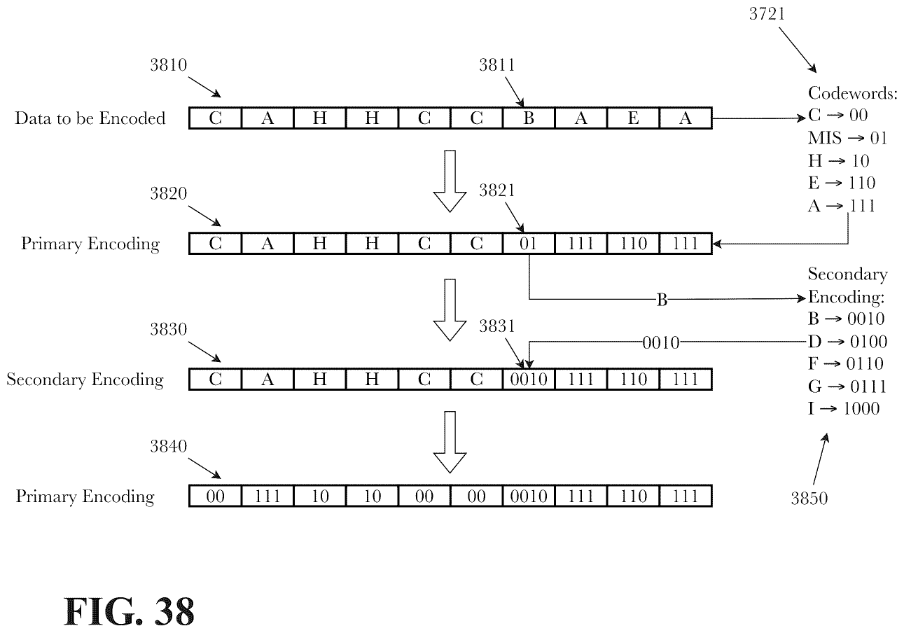

FIG. 38 is a diagram illustrating an exemplary encoding using a codebook and secondary encoding. In this example, the sourceblocks A-I 3701, codebook 3720, and codewords 3721 are the same as in FIG. 37. Codebook 3720 contains the same codewords 3721 The data to be encoded 3810 consists of a stream of sourceblocks in the order from first to last: AEABCCHHCC. The first three sourceblocks processed are AEA, and are encoded as 111, 110, and 111 using codebook 3720 as the primary encoding method as shown at 3820. However, the fourth sourceblock 3811 is B, which is not contained in codebook 3720. Thus, when B is processed, codebook 3720 returns the mismatch code 01 3821, which triggers a secondary encoding method 3820 for encoding sourceblock B. In this example, secondary encoding method 3850 is a suboptimal 4-bit encoding of sourceblocks A-I 3701, wherein the codewords for B, D, F, G, and I are as follows: B→0010, D→0100, F→0110, G→0111, and I→1000. The secondary encoding 3820 of B is 0010, which is inserted into the encoded data stream 3831. From there, encoding reverts to the primary encoding method using codebook 3720 as shown at 3840, and the remainder of the sourceblocks are encoded according to codebook 3720. Note that while the secondary encoding is shown as being performed while primary encoding is occurring, other embodiments may allow primary encoding to complete before performing secondary encoding, and may even allow the primary encoding with the mismatched codewords to be stored such that the secondary encoding is performed at a later time, although such embodiments would need some record of the association between the mismatch codeword and the sourceblock that it replaced (which could be done by several means including, but not limited to, reprocessing the data to be encoded, storing a separate record of the associations, and using multiple mismatch codewords.

Decoding of data compacted using this method is the reverse of the encoding process. A stream of codewords are received. Any codewords from the codebook (the primary encoding) are looked up in the codebook to retrieve their associated sourceblocks. Any codewords from secondary encoding are looked up using the secondary encoding method to retrieve their associated sourceblocks.

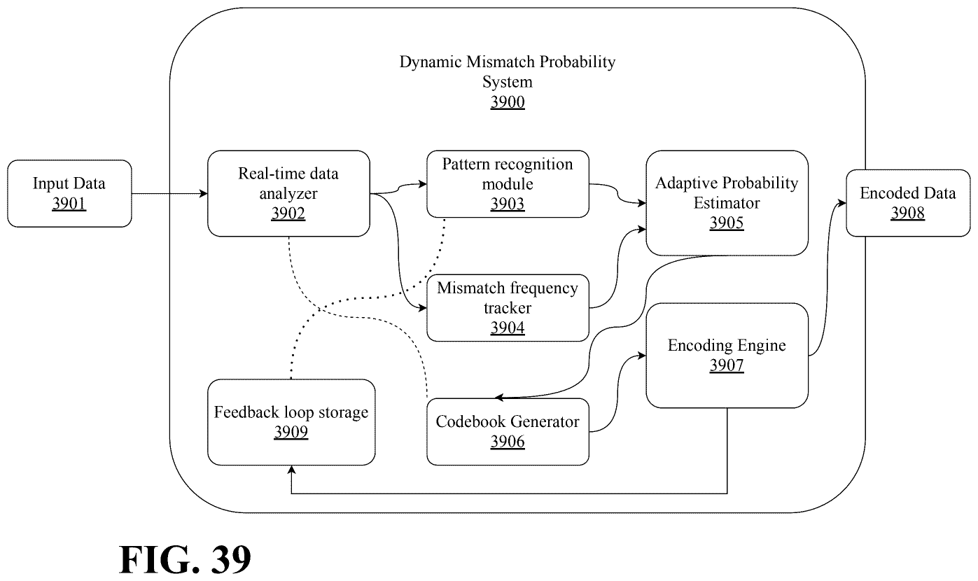

FIG. 39 is a block diagram illustrating an exemplary system architecture for a dynamic mismatch probability estimation according to an embodiment of the invention. The dynamic mismatch probability system 3900 significantly enhances the static mismatch probability estimation approach described by implementing real-time adaptation mechanisms that continuously refine probability estimates based on observed data patterns and actual mismatch frequencies.

As shown in FIG. 39, input data 3901 is first processed by a real-time data analyzer 3902, which performs sourceblock pattern analysis and data type classification on the incoming data stream. The real-time data analyzer 3902 examines characteristics of the input data such as entropy distribution, repetition patterns, and structural features to determine optimal processing parameters for subsequent encoding. Unlike the static analysis approach, this real-time analysis enables the system to adapt to changing data characteristics within a single data stream, thereby improving encoding efficiency across heterogeneous data sets.

The analyzed data is simultaneously routed to a pattern recognition module 3903 and a mismatch frequency tracker 3904. The pattern recognition module 3903 identifies historical patterns and correlations within the data stream that may indicate the likelihood of specific sourceblocks appearing. This module utilizes both statistical models and machine learning algorithms to recognize data signatures that correlate with specific mismatch probability requirements. The mismatch frequency tracker 3904 monitors actual mismatch occurrences during encoding operations and maintains statistical aggregations of these events, including frequency, distribution, and contextual information about when and where mismatches occur within data streams.

Both the pattern recognition module 3903 and mismatch frequency tracker 3904 feed their outputs to the adaptive probability estimator 3905, which serves as the core intelligence of the dynamic system. The adaptive probability estimator 3905 integrates multiple probabilistic models and dynamically adjusts mismatch probability estimates based on both predicted patterns and observed mismatch frequencies. Unlike the static estimators that relies on primarily training data statistics, this adaptive estimator continuously refines its probability calculations based on real-time observations, implementing a sophisticated multi-model integration approach that can weight different probability estimation techniques according to their demonstrated accuracy for particular data types.

The dynamically calculated mismatch probability estimate is then provided to the codebook generator 3906, which creates encodings that incorporate the optimized mismatch codeword placements within the Huffman or other entropy coding trees. The codebook generator 3906 dynamically constructs codebooks that reflect the current best estimation of mismatch probabilities, potentially generating different codebooks for different segments of the same data stream if the data characteristics vary significantly. These codebooks are then utilized by the encoding engine 3907 to perform both primary encoding (using the dynamically generated codebooks) and secondary encoding (for handling sourceblocks that result in mismatches).

The encoding engine 3907 produces the encoded data 3908 as output and also provides performance metrics to the feedback loop storage 3909, which maintains a historical record of encoding performance, including accuracy of mismatch predictions, encoding efficiency metrics, and correlations between data characteristics and optimal mismatch probability values. This historical performance data is fed back into the pattern recognition module 3903, enabling the system to learn from past experiences and continuously improve its probability estimation accuracy.

Additionally, the codebook generator 3906 provides feedback to earlier stages of the pipeline, allowing the system to adjust analysis parameters based on observed encoding outcomes. This comprehensive feedback mechanism creates a self-improving system that becomes increasingly accuracy in its mismatch probability estimations over time, resulting in progressively more efficient data encoding.

The dynamic mismatch probability system 3900 significantly improves upon the static estimation methods by implementing a closed-loop adaptive system that can respond to changing data characteristics in real-time and learn from historical performance to optimize future encoding operations. This dynamic approach enables substantially better compression efficiency, particularly for heterogeneous or rapidly evolving data streams where static probability estimates would quickly become suboptimal.

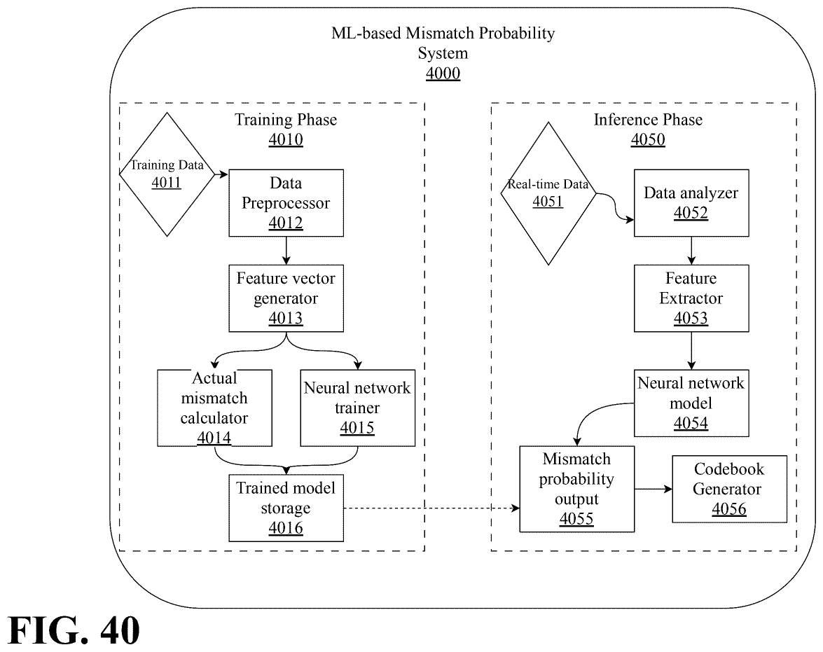

FIG. 40 is a block diagram illustrating a machine learning-based mismatch probability estimation system 4000, according to an embodiment of the invention. This system represents a significant advancement over the statistical approaches by leveraging neural network technology to capture complex, non-linear relationships between data characteristics and optimal mismatch probability values. The system is divided into two distinct operational phases: a training phase 4010 and an inference phase 4050.

In the training phase 4010, the system begins with training data 4011 comprising diverse data sets with known mismatch characteristics. This training data 4011 is processed by a data preprocessor 4012, which performs essential feature extraction operation including entropy analysis, data type classification, pattern recognition, and structural decomposition. The data preprocessor 4012 transforms raw data into structured information that highlights characteristics relevant to mismatch probability estimation. A feature vector generator 4013 then converts this processed information into mathematical representations suitable for neural network training, creating multi-dimensional feature vectors that encode data properties such as entropy distributions, block frequencies, data type indicators, and a plurality of pattern metrics that correlate with mismatch probability.

Concurrently, an actual mismatch calculator 4014 analyzes the training data sets to determine the ground truth mismatch frequencies for each data set when encoded with codebooks. This calculates the actual optimal mismatch probability values that will serve as the target outputs during neural network training. The neural network trainer 4015 then combines the feature vectors and corresponding optimal mismatch probability values to train a multi-layer neural network, using supervised learning techniques such as backpropagation to adjust the network weights and minimize prediction error. The neural network architecture comprises multiple interconnected layers, including input nodes for feature vectors, hidden layers for complex pattern recognition, and output nodes that produce the estimation mismatch probability. Once trained to a sufficient accuracy level, the optimized neural network model is stored in trained model storage 4016 for subsequent use during inference operations.

The inference phase 4050 operates when the system processes new, previously unseen data for encoding. Real-time data 4051 enters the system and is analyzed by a data analyzer 4052, which performs similar operations to this conducted during the training phase, but optimized for real-time performance. The feature extractor 4053 then generates the same types of feature vectors produced during training, ensuring compatibility within the trained neural network model. These feature vectors are fed into the neural network model 4054, which has been transferred from the trained model storage 4016. The neural network processes these inputs through its multiple layers, leveraging the patterns learned during training to produce a mismatch probability output 4055 that represents the optimal mismatch probability estimation for the specific characteristics of the current data stream. This probability value is then sent to the codebook generator 4056 to create optimized encodings with appropriately placed mismatch codewords within the Huffman or other entropy coding trees.

The machine learning-based approach depicted in FIG. 40 provides several advantages over the mathematical formulas. First, it can capture complex, non-linear relationships between data characteristics and optimal mismatch probabilities that would be difficult or impossible to express through explicit mathematical formulations. Second, it can automatically adapt to different data types without requiring manual tuning or formula adjustments. Third, with sufficient training across diverse data sets, the neural network can generalize to novel data patterns, providing robust performance across a wide range of applications. Finally, the system can be continuously improved through additional training with new data, enabling progressive refinement of mismatch probability estimations over time.

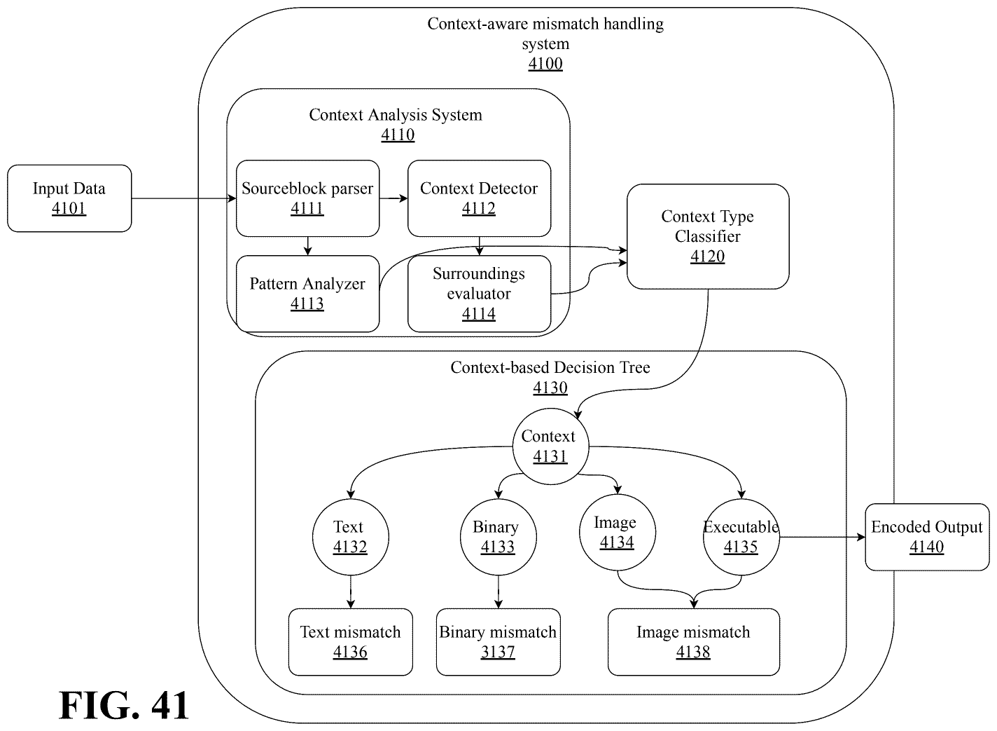

FIG. 41 is a block diagram illustrating a context-aware mismatch handling system 4100 that represents a significant enhancement to the mismatch handling approach. This advanced system analyzes the contextual characteristics of data to determine the most appropriate mismatch handling strategy, leading to more efficient encoding and improved compression performance across diverse data types.

As shown in FIG. 41, the system begins by receiving input data 4101, which is directed to a context analysis system 4110. This analysis system comprises several specialized components that work in concert to comprehensively evaluate the context in which potential mismatches may occur. The sourceblock parser 4111 first decomposes the incoming data stream into appropriately sized sourceblocks for detailed examination. Unlike a general sourceblock handling approach, this parser can adaptively adjust sourceblock boundaries based on detected data patterns, ensuring optimal alignment with natural data structures such as text words, image blocks, or executable code segments.

The parsed sourceblocks are then processed by both the context detector 4112 and pattern analyzer 4113. The context detector 4112 identifies the general context category of the data by examining characteristic signatures and structures. For example, it can recognize ASCII text patterns, binary data sequences, image-specific pixel arrangements, or executable code headers. Simultaneously, the pattern analyzer 4113 performs a more granular examination of recurring patterns within the sourceblocks, identifying repetition, entropy variations, and statistical distributions that may indicate specific data types or formats.

The surroundings evaluator 4114 examines the data surrounding potential mismatch points, analyzing how the context flows across sourceblock boundaries. This is particularly important because the optimal handling of a mismatch often depends not just on the mismatch sourceblock itself, but also on adjacent sourceblocks that provide contextual continuity. For instance, in text data, understanding the surrounding words can help predict the likely content of a mismatched sourceblock, while in image data, gradient patterns across block boundaries can inform more accurate reconstruction strategies.

The combined outputs from the context analysis system 4110 feed into the context type classifier 4120, which categorizes the data into specific context types including text, binary, image, and executable formats. This classifier employs sophisticated pattern recognition algorithms to determine the most likely category for each segment of data, assigning confidence scores to each classification. The classifier may identify multiple potential context types for ambiguous data, with associated probability weights that inform subsequent processing decisions.

The classified context information is then passed to the context-based decision tree 4130, which serves as the central intelligence of the mismatch handling system. The decision tree begins at a root node 4131 that evaluates the overall content classification and directs processing through appropriate branch nodes based on the determined context type. For text data, processing flows to the text context node 4132, which incorporates dictionary-based approaches and language pattern recognition optimized for textual content. Binary data is directed to the binary context node 4133, which employs specialized pattern matching strategies for zero-one sequences and structured binary formats. Image data flows to the image context node 4134, which leverages knowledge of pixel patterns and gradient structures common in visual content. Executable code is handled by the executable context node 4135, which recognizes the unique characteristics of program instructions and data structures.

Each context branch ultimately connects to a specialized mismatch handler optimized for that particular data type. The text mismatch handler 4136 employs linguistic models and word prediction techniques to handle mismatches in textual data. The binary mismatch handler 4137 utilizes statistical models of binary patterns and format-specific knowledge to reconstruct mismatched binary blocks. The image mismatch handler 4138 applies principles of image reconstruction and visual coherence to handle mismatches in image data, preserving visual quality even when exact matches are unavailable. An executable mismatch handler would similarly apply program structure knowledge to handle mismatches in code segments.

The context-aware system also includes an example data analysis visualization, showing how different data types (text, binary, image, and executable) are identified and processed according to their specific characteristics. This visual representation demonstrates how the system adapts its analysis approach based on detected data patterns, illustrating the flexibility of the context-aware methodology.

After appropriate context-specific handling of any mismatches, the system produces encoded output 4140 that has been optimized according to the specific contextual requirements of the data. This context-aware approach significantly improves upon the generic mismatch handling described in the original disclosure by tailoring encoding strategies to the specific characteristics of different data types, resulting in more efficient compression, better reconstruction quality, and improved overall system performance.

The context-aware mismatch handling system 4100 represents a substantial advancement in entropy encoding technology, enabling more intelligent and adaptive processing of diverse data types within a unified encoding framework. By recognizing and leveraging the contextual characteristics of data, the system can make more informed decisions about mismatch handling strategies, ultimately leading to superior compression performance across a wide range of applications and data formats.

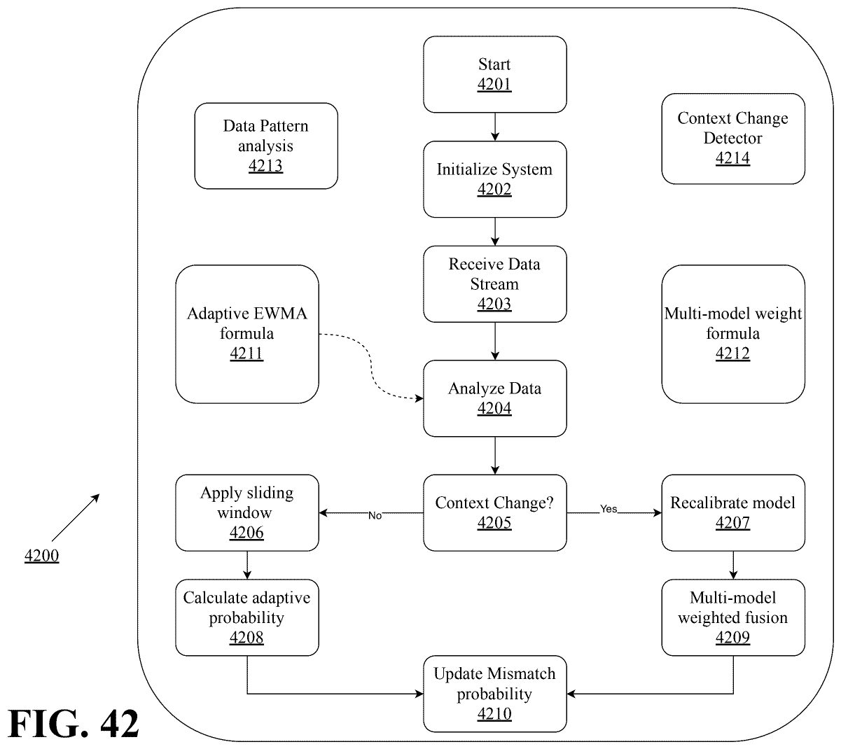

FIG. 42 is a method diagram for an adaptive mismatch probability calculation 4200 that significantly advances beyond the static probability estimation approaches. This dynamic method continuously refines probability estimates through real-time analysis of data patterns, context detection, and feedback-driven adaptation, resulting in substantially improved encoding efficiency across diverse and evolving data streams.

The method begins at start point 4201, proceeding to system initialization 4202, where default parameters are established based on historical performance data or pre-configured settings. These parameters include initial mismatch probability values, adaptation rates, window sizes for statistical analysis, and weighting coefficients for multi-model fusion. These initialization values serve only as starting points that will be dynamically adjusted as the system processes data and learns from observed patterns.

Following initialization, the system receives and buffers the input data stream at step 4203. This buffering operation creates a temporal window of data that enables the system to analyze not just individual sourceblocks but also the relationships and patterns that exist across multiple blocks. The buffer size is dynamically adjusted based on the detected data characteristics, with larger buffers employed for data exhibiting long-range dependencies and smaller buffers used for more localized patterns, optimizing the tradeoff between analysis depth and processing efficiency.

At step 4204, the system conducts a thorough analysis of the buffered data to extract key features relevant to mismatch probability estimation. This analysis leverages multiple techniques in the data pattern analysis 4213, including content type detection to identify the general category of data (e.g., text, image, executable), entropy measurement to quantify information density and randomness, and statistical sampling to efficiently process large volumes of data while maintaining representativeness. The analysis provides a multi-dimensional feature vector that characterizes the current data segment and serves as input to subsequent decision processes.

A critical decision point occurs at step 4205, where the system determines whether a significant context change has occurred in the data stream. This determination is made using the context change detector methods 4214, including pattern discontinuity detection to identify abrupt shifts in data characteristics, statistical divergence measurements to quantify the difference between recent and historical data distributions, and entropy shift detection to recognize changes in information density that may indicate transitions between different data types or formats. The context change detection employs adaptive thresholds that adjust based on the observed variability of the data stream, ensuring robust detection across different scenarios.

If no context change is detected, the system proceeds along the left branch to apply sliding window analysis at step 4206. This technique maintains a record of recent mismatches and their surrounding contexts, enabling the system to recognize local patterns in mismatch occurrence. The sliding window dynamically adjusts its size based on the observed temporal dependencies in the data, with larger windows used for data exhibiting long-range correlations and smaller windows for more locally dependent structures. This adaptive windowing ensures optimal capture of relevant patterns while minimizing computational overhead.

The system then calculates an adaptive probability at step 4208 using the enhanced exponentially weighted moving average (EWMA) formula 4211. This formula, μₙ=(1−βₙ)μₙ₋₁+βₙXₙ, where βₙ=C·log(n)/n, represents a significant advancement over the static formulations in the original disclosure. The adaptation coefficient βₙ now varies with both the amount of data processed (n) and an adaptive parameter C that adjusts based on observed data characteristics and mismatch patterns. This dynamic adaptation enables faster response to genuine shifts in data patterns while maintaining stability against transient fluctuations, addressing a key limitation of the original formulation.

If a context change is detected, the system instead follows the right branch to recalibrate the model at step 4207. This recalibration involves resetting certain adaptation parameters to enable rapid adjustment to the new context, while preserving accumulated knowledge that remains relevant. The recalibration process selectively preserves or discards historical information based on a relevance assessment that considers both the magnitude of the context change and the specific parameters affected by the transition, enabling targeted adaptation without unnecessary loss of valuable historical data.

Following recalibration, the system performs multi-model weighted fusion at step 4209, applying the multi-modal weight formula in 4212: q=Σ wᵢqᵢ, where wᵢ=performance (modelᵢ)/Σ performance (modelⱼ). This approach maintains multiple probability models optimized for different contexts and combines them using weights determined by their relative performance or recent data. The performance assessment continuously updates based on observed encoding efficiency, ensuring that the most accurate models for the current context receive the highest weights. This multi-model approach enables robust handling of complex or ambiguous data patterns that may or may not conform clearly to a single context category.

Both branches converge at the update mismatch probability step 4210, where the system applies the calculated probability adjustments to update the current mismatch probability estimate. This updated probability is then used for subsequent encoding operations, ensuring that the codebook generation process incorporates the most current and accurate mismatch expectations. The updated probability also feeds back into the analysis process for future data segments, creating a continuous learning and adaptation cycle.

This feedback loop represents a fundamental enhancement over the approach, enabling the system to progressively refine its probability estimates based on observed performance. As the system processes more data, it accumulates knowledge about mismatch patterns and their relationship to data characteristics, leading to increasingly accurate probability estimates that result in more efficient encoding across diverse and evolving data streams.

The adaptive mismatch probability calculation method illustrated in FIG. 42 addresses a key limitation by transforming mismatch probability estimation from a static, formula-based approach to a dynamic, learning-based system that continuously optimizes its estimates based on observed data patterns and encoding performance. This advancement significantly improves encoding efficiency, particularly for heterogeneous or evolving data streams where static probability estimates would rapidly become suboptimal, representing a substantial technological contribution to the field of entropy encoding with mismatch probability estimation.

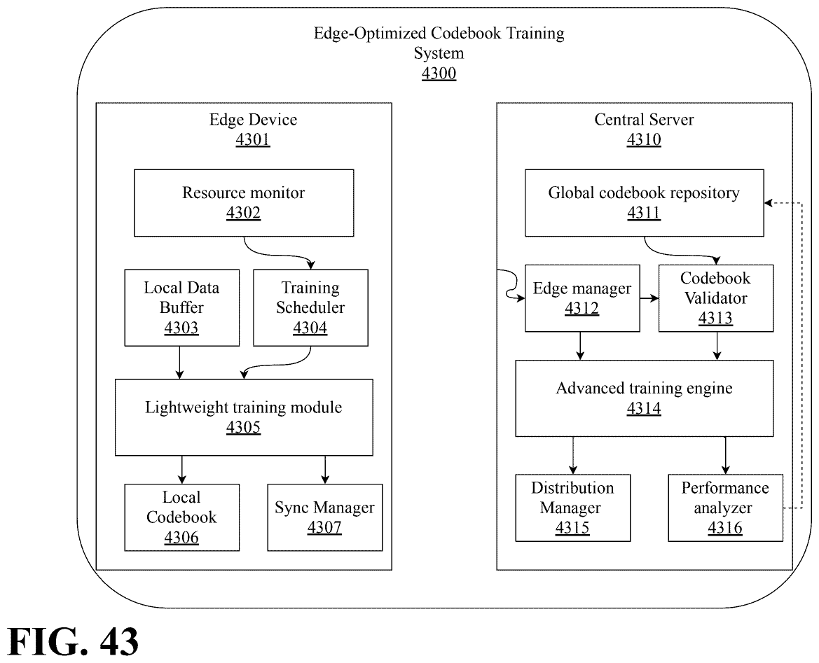

FIG. 43 is a block diagram illustrating an innovative edge-optimized codebook training system 4300 to resource-constrained environments, addressing critical limitations by enabling efficient codebook training and maintenance at the network edge. This distributed architecture strategically balances computational load between edge devices and a central server, optimizing for limited resources while maintaining codebook quality and system-wide consistency.

The architecture is divided into two primary components: the edge device 4301 operating in a resource-constrained environment and the central server 4310 providing high-performance computational support. These components are connected via a secure, bandwidth-efficient network channel 4320 that facilitates essential data exchange while minimizing communication overhead.

Within the edge device 4301, a resource monitor 4302 continuously tracks critical system metrics including CPU utilization, memory availability, and power consumption. Unlike the resource-intensive approaches, this enables adaptive behavior based on real-time device conditions, ensuring that codebook training activities do not adversely impact device performance or battery life. The resource monitor feeds this information to the training scheduler 4304, which intelligently determines optimal times for codebook training operations based on current resource availability, device usage patterns, and training priority levels. This scheduler implements sophisticated algorithms that can defer non-critical training during periods of resource contention or accelerate training when excess capacity is available, creating opportunistic training windows that leverage otherwise idle processing cycles.

The local data buffer 4303 collects and maintains a representative sample of data passing through the edge device, carefully selected to capture the device's unique data characteristics and usage patterns. This buffer implements efficient sampling techniques that prioritize diversity and representativeness while minimizing storage requirements, enabling even severely resource-constrained devices to maintain useful training data sets. The data is then processed by the lightweight training model 4305, which represents a significant advancement over the training approaches. This module implements computationally efficient, memory-optimized training algorithms specifically designed for edge environments, incorporating techniques such as incremental learning, parameter quantization, and sparse updates to minimize resource consumption while maintaining training quality.

The resulting codebook is stored in the local codebook repository 4306, which employs memory optimization techniques to maintain a compact representation that balances encoding efficiency against storage requirements. These techniques include structural compression, reference deduplication, and adaptive precision control that scales representation detail based on the statistical importance of each codebook entry. The synchronization manager 4307 coordinates interactions with the central server, implementing power optimization techniques such as batched communications, timing transmissions during periods of low energy cost, and adaptively adjusting synchronization frequency based on observed data patterns and battery status.

On the central server side 4310, the global codebook repository 4311 maintains version-controlled codebooks for all devices in the network, tracking their evolutionary history and relationships. This repository implements data structures that enable efficient storage, comparison, and retrieval of codebooks while preserving their historical relationships and derivation history. The edge manager 4312 coordinates communications with distributed edge devices, maintaining device state information, scheduling interactions based on network conditions and device availability, and prioritizing updates based on performance impact assessments.

The codebook validator 4313 performs critical quality assurance functions, rigorously evaluating codebooks received from edge devices to ensure they meet system-wide quality standards, are free from corruption or inconsistencies, and provide satisfactory performance across diverse data types. Codebooks that pass validation are forwarded to the advanced training engine 4314, which conducts more computationally intensive optimization processes leveraging the server's abundant resources. This engine implements sophisticated training methodologies including deep statistical analysis, cross-device pattern correlation, and ensemble optimization techniques that would be impractical to execute on resource-constrained edge devices.

The distribution manager 4315 handles the dissemination of optimized codebooks back to edge devices, implementing model compression techniques that optimize codebooks for specific device constraints while preserving their essential statistical properties. These techniques including precision scaling, structured pruning, and component quantization, tailored to the specific capabilities of each target device. The performance analyzer 4316 continuously evaluates system-wide encoding efficiency through comprehensive performance metrics, identifying optimization opportunities and providing feedback to improve future training cycles.

The resource indicators represent the current resource utilization on edge devices, including CPU, memory, and battery gauges that provide immediate insight into system constraints. These indicators are continuously updated based on telemetry from the resource monitor, enabling adaptive system behavior that respects device limitations.

The edge device codebook training architecture illustrated in FIG. 43 represents a transformative advancement, enabling efficient codebook development and maintenance in resource-constrained environments. By strategically distributing computational load, optimizing for device constraints, and implementing efficient synchronization mechanisms, this architecture extends the applicability to a vast range of edge computing scenarios, from IoT devices and mobile platforms to embedded systems and sensor networks, significantly broadening its potential impact and utility.

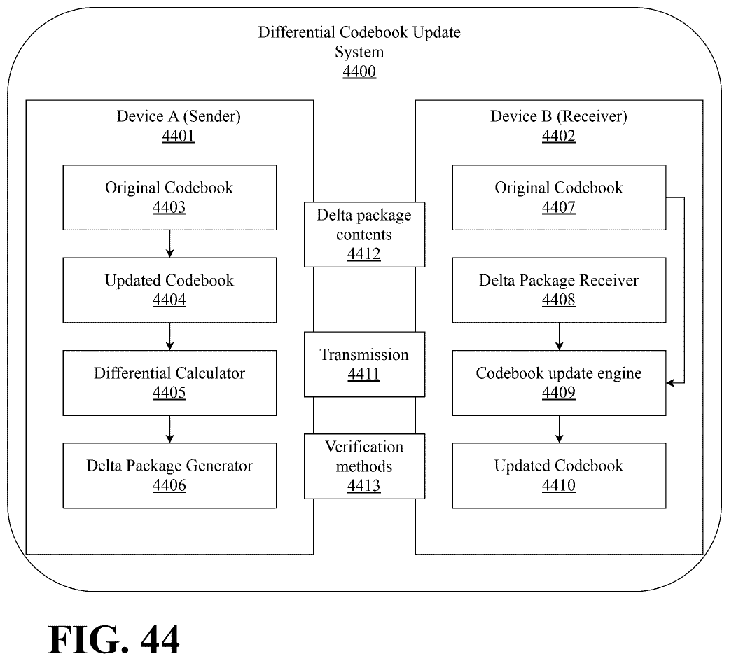

FIG. 44 is a block diagram illustrating a differential codebook update system 4400 that addresses a critical limitation by enabling efficient synchronization of codebooks across distributed environments with minimal bandwidth consumption. This sophisticated system employs delta encoding techniques to identify, package, and transmit only the changes between codebook versions, significantly reducing network overhead while maintaining codebook consistency across devices.

The system architecture is structured around two primary nodes: Device A (sender) 4401 and Device B (receiver) 4402, connected through a transmission channel 4411 that carries only the delta package rather than complete codebooks. This approach represents a substantial improvement over full codebook transmission methods that would be implied, particularly in bandwidth-constrained or high-latency network environments.

On Device A (sender) 4401, the process begins with an original codebook 4403 (Version 1.0) that has undergone modifications to produce an updated codebook 4404 (Version 1.1). These modifications may result from local training, adaptive optimization, or manual adjustments to improve encoding efficiency for specific data types. Rather than transmitting the entire updated codebook to synchronize with other devices, the differential calculator 4405 performs a comparison between the original and updated codebooks to precisely identify all changes.

The differential calculator 4405 implements advanced change detection algorithms that go beyond simple binary comparison to recognize structural and semantic modifications. These algorithms can detect multiple types of changes including added codewords (entirely new entries), removed codewords (entries that no longer exist), and modified codewords (entries whose values have changed but maintain the same semantic role). The calculator also identifies unchanged portions that do not require transmission, substantially reducing redundant data transfer.

The detected changes are passed to the delta package generator 4406, which creates a highly compact, structured representation of the differences. This generator employs specialized encoding techniques optimized for the types of modifications typically found in codebooks, including run-length encoding for sequential changes, reference-based encoding for similar patterns, and context-aware compression that leverages the structural properties of codebooks. The resulting delta package is considerably smaller than the full codebook.

Within the delta package contents 4412 there are four key components: version information (to ensure compatibility and proper sequencing), added codewords (new entries that must be incorporated), removed codewords (entries that must be deleted), and modified codewords (entries requiring value updates). This structured approach enables precise reconstruction of the updated codebook while minimizing transmission payload.

The transmission channel 4411 carries only this delta package from Device A to Device B, representing a fraction of the data that would be required to transmit the entire codebook. This efficiency is particularly valuable in environments with limited bandwidth, high transmission costs, or energy constraints where minimizing network communication is essential.

On Device B (receiver) 4402, the process begins with its own copy of the original codebook 4407 (Version 1.0), which must be synchronized with the updates made on Device A. The delta package receiver 4408 accepts the incoming delta package and performs integrity verification to ensure the package was received without corruption or tampering. This verification employs methods 4413 including checksum validation to detect transmission errors and conflict resolution logic to handle potential inconsistencies between the base codebooks on the sender and receiver.

After successful verification, the codebook update engine 4409 systematically applies the changes specified in the delta package to the original codebook. This engine implements sophisticated change application logic that handles dependencies between modifications, ensures proper sequencing of operations, and maintains the structural integrity of the codebook throughout the update process. The engine first applies removals to eliminate deprecated entries, then incorporates additions and modifications to build the updated version, carefully managing any potential conflicts or edge cases that might arise during the transformation.

The result is an updated codebook 4410 (Version 1.1) on Device B that precisely matches the updated codebook 4404 on Device A, achieved with minimal data transmission and processing overhead. This synchronization ensures consistent encoding behavior across distributed systems, which is essential for maintaining interoperability in multi-device environments.

The differential codebook update system represented in FIG. 44 provides several significant advantages. By transmitting only the differences between codebook versions rather than complete codebooks, it dramatically reduces bandwidth requirements, enabling efficient synchronization even in constrained network environments. The structured delta package format ensures precise reconstruction of updated codebooks while minimizing transmission overhead. The verification mechanisms enhance reliability by detecting and resolving potential inconsistencies or transmission errors. Together, these capabilities enable robust, efficient maintenance of synchronized codebooks across distributed systems, addressing a critical requirement for deploying the encoding technology in networked environments.

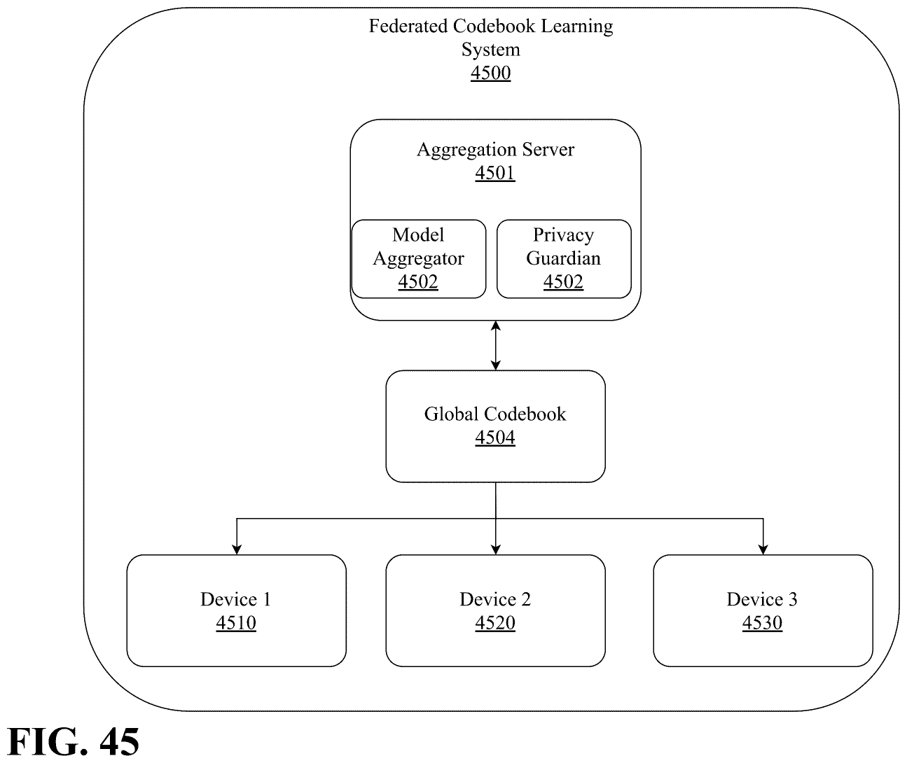

FIG. 45 is a block diagram illustrating a federated codebook learning system 4500 over the centralized training approach. This subsystem enables collaborative codebook development across multiple distributed devices while maintaining strong privacy guarantees for the underlying data, addressing critical requirements for modern distributed systems.

The aggregation server 4501, serves as the central coordination point for the federated learning process without requiring direct access to the training data on participating devices. The server contains two primary components: the model aggregator 4502, which implements sophisticated algorithms for combining model updates from multiple devices into a coherent global codebook, and the privacy guardian 4503, which enforces privacy constraints throughout the aggregation process to prevent the extraction of sensitive information from contributed updates. Unlike traditional training approaches, this server never directly accesses or stores the raw training data, operating exclusively on privacy-protected model updates provided by participating devices.

The global codebook 4504 represents the collaboratively trained knowledge repository that synthesizes insights from all participating devices. This codebook maintains version control and provenance tracking to document the evolutionary history of the model while enabling rollback capabilities if needed. The global model serves as the foundation for device-specific customization, providing a strong starting point that individual devices can further adapt to their particular data patterns and requirements.

The system incorporates multiple participating devices (4510, 4520, 4530), each with unique data characteristics and usage patterns. Device 1 4510 represents the first participant in the federated learning network, containing local data that remains exclusively on the device throughout the entire process. This local data may include sensitive information, proprietary content, or regulated data that cannot be shared due to privacy, security, or compliance requirements. The local trainer performs model training directly on the device, using the local data to generate updates to the global codebook without extracting or transmitting the underlying training examples. The privacy filter applies additional protection mechanisms to ensure that the model updates do not inadvertently leak sensitive information, implementing techniques such as gradient clipping, noise addition, and outlier removal to sanitize the updates before transmission.

Similar components exist on Device 2 4520 (local data, local trainer, privacy filter) and Device 3 4530 (local data, local trainer, privacy filter), each operating independently on their respective devices to generate privacy-preserving updates based on their unique local data. This distributed approach enables the system to leverage diverse data sources without centralizing the data, addressing privacy concerns while potentially improving model robustness through exposure to varied training examples.

The system employs a variety of privacy techniques to safeguard sensitive information throughout the federated learning process. Differential privacy mechanisms add calibrated noise to model updates to mathematically guarantee that individual training examples cannot be extracted or inferred from the transmitted data. Secure aggregation protocols enable the combination of model updates from multiple devices without revealing the individual contributions, using cryptographic techniques to ensure that only the aggregate is visible to the central server. Knowledge distillation approaches extract generalized patterns without exposing the specific examples that generated those patterns, further preserving privacy while maintaining model quality.

Contribution weighting provides mechanisms for appropriately balancing the influence of different devices on the global model. Data quality metrics assess the reliability and representativeness of each device's training data, allowing the system to emphasize contributions from devices with higher-quality data. Device reliability scores track the historical performance and consistency of each participant to mitigate the impact of potentially malicious or malfunctioning devices. Contribution importance evaluations analyze the uniqueness and value of each device's updates, giving greater weight to novel insights that substantially improve the global model while reducing the influence of redundant or low-value contributions.

The learning phases illustrate the cyclical nature of the federated learning process. During the download phase, devices receive the current version of the global codebook as a starting point for local training. The train phase occurs exclusively on each device, with the local trainer using device-specific data to generate model updates that improve performance for that device's particular usage patterns. In the upload phase, privacy-filtered updates are transmitted to the aggregation server, containing only the necessary information to improve the global model without exposing the underlying training data.

The aggregation methods showcase different approaches for combining model updates from multiple devices. Simple averaging combines all device contributions with equal weight, providing a baseline aggregation strategy that works well for homogeneous device populations. Weighted aggregation applies varying importance to different device contributions based on factors such as data quality, device reliability, and update significance. Ensemble techniques maintain multiple specialized sub-models within the global codebook, each potentially influenced by different device subsets, enabling more nuanced handling of diverse data patterns across the device population.

The federated codebook learning system illustrated in FIG. 45 addresses several critical limitations of the training approaches implied in the original disclosure. By enabling collaborative model development without centralizing sensitive data, it resolves privacy concerns that would otherwise limit adoption in regulated or security-sensitive environments. The distributed training approach leverages diverse data sources across multiple devices, potentially improving model robustness and performance compared to training on any single data source. The privacy-preserving update mechanisms ensure that sensitive information remains protected throughout the learning process, enabling participation by devices that handle confidential or regulated data. Together, these capabilities substantially extend the applicability and value of the mismatch probability estimation technology described in the original disclosure, making it suitable for deployment in modern distributed systems with strict privacy requirements.

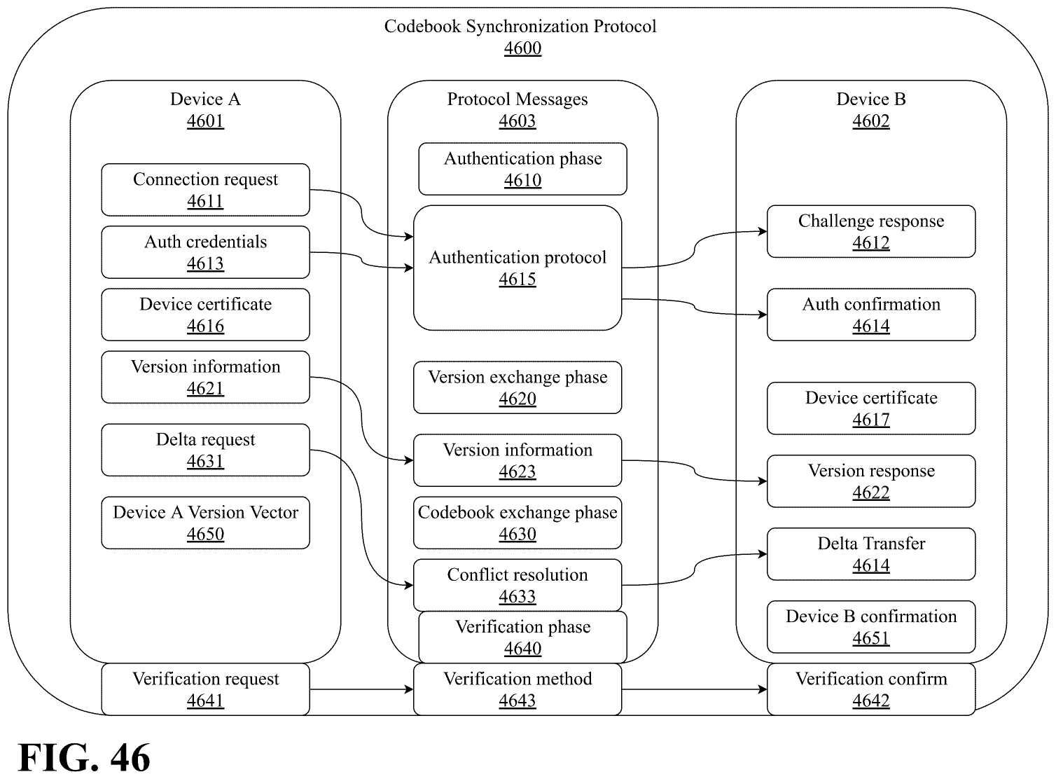

FIG. 46 is a block diagram illustrating a comprehensive codebook synchronization protocol 4600. This protocol enables secure, efficient, and reliable codebook synchronization between devices while addressing critical considerations including authentication, version management, conflict resolution, and verification.

The protocol is structured as a multi-phase communication sequence between two devices—Device A 4601 and Device B 4602—with protocol messages 4603 exchanged through a secure communication channel. This structured approach ensures methodical progression through the synchronization process while maintaining security and data integrity throughout the exchange.

The protocol begins with an authentication phase 4610, which establishes a secure, trusted connected between the participating devices. This critical security layer is essential for protecting proprietary codebooks from unauthorized access or tampering. Device A initiates the process by sending a connection request 4611 to Device B, signaling its intent to establish a synchronization session. Device B responds with a challenge response 4612, implementing a challenge-response authentication mechanism that prevents replay attacks and verifies the identity of the requesting device. Device A then provides its authentication credentials 4613, which may include digital signatures, device certificates, or other cryptographic proof of identity. Upon successful verification of these credentials, Device B sends an authentication confirmation 4614, establishing a mutually authenticated secure channel for subsequent communications.

The authentication protocol 4615 details the specific security mechanisms employed during this phase, including mutual device authentication to verify the identity of both participants, a challenge-response method that prevents replay attacks, public key infrastructure that provides cryptographic identity verification, and secure channel establishment that protects all subsequent communications from eavesdropping or tampering. The device certificates 4616 and 4617 provide unique cryptographic identities for Device A and Device B, respectively, serving as the foundation for the trust relationship between the devices.

Once a secure channel is established, the protocol proceeds to the version exchange phase 4620, where devices compare their respective codebook versions to determine what updates are needed. This phase addresses a significant limitation in the original disclosure by providing a mechanism for efficiently identifying and resolving version discrepancies between codebooks. Device A transmits its version information 4621, which includes metadata about its current codebook state, such as version numbers, timestamps, and hash values that uniquely identify its codebook content. Device B responds with its version response 4622, providing similar metadata about its own codebook state.

The version information details 4623 describe the specific techniques used during this exchange, including codebook hash verification that validates the integrity of the codebooks and version vector exchange that precisely tracks the evolutionary history of the codebooks across multiple devices. Version vectors 4650 and 4651 illustrate this concept, showing how each device maintains a vector of version counters for all devices in the system. In this example, Device A's version vector [A: 5, B: 3, C: 7] indicates it has incorporated 5 updates from Device A, 3 updates from Device B, and 7 updates from Device C. Similarly, Device B's version vector [A: 4, B: 7, C: 7] shows it has incorporated 4 updates from Device A, 7 updates from Device B, and 7 updates from Device C. By comparing these vectors, the devices can precisely determine which updates each is missing, enabling targeted, efficient synchronization.

Following version compression, the protocol enters the codebook exchange phase 4630, where the actual transfer of missing codebook entries occurs. Device A issues a delta request 4631, specifying exactly which updates it needs based on the version comparison. Device B responds with a delta transfer 4632, transmitting only the necessary codebook differences rather than the entire codebook. This differential approach dramatically reduces bandwidth requirements compared to full codebook transfers, addressing efficiency concerns.

The conflict resolution module 4633 is critical of this phase, implementing strategies for handling conflicting updates that may occur when multiple devices independently modify the same codebook entries. The module supports multiple resolution strategies, including last-writer-wins, which automatically selects the most recent update based on timestamps, and merge conflicting entries, which intelligently combines divergent updates when possible to preserve the valuable contributions from both sources. This sophisticated conflict management goes well beyond the capabilities implied in the original disclosure, enabling robust operation in complex distributed environments where concurrent modifications are common.

The final stage of the protocol is the verification phase 4640, which confirms the successful completion of the synchronization process and ensures that both devices now have consistent codebook states. Device A initiates this phase by sending a verification request 4641, asking Device B to confirm the integrity of the synchronized codebook. Device B performs the necessary validation and responds with a verification confirmation 4642, indicating that the synchronization has been successfully completed and the codebooks are now in a consistent state.

The verification method 4643 details the specific technique used to validate the synchronization, which in this case is checksum comparison. This approach generates cryptographic checksums of the entire codebook on both devices and compares them to ensure bit-level consistency, providing a strong guarantee that the synchronization has been successful and both devices now have identical codebooks.

Throughout the entire exchange, a secure communication channel-visually represented by the dashed lines on either side of the protocol messages-protects all communications between the devices. This channel, established during the authentication phase, employs cryptographic protocols to ensure confidentiality, integrity, and authenticity of all exchanged messages, preventing unauthorized access to proprietary codebook data or tampering with the synchronization process.

The codebook synchronization protocol illustrated in FIG. 46 represents a significant advancement over the approaches implied in the original disclosure, addressing critical requirements for secure, efficient, and reliable codebook synchronization in distributed environments. By implementing sophisticated authentication, version management, differential updates, conflict resolution, and verification mechanisms, this protocol enables robust operation across diverse deployment scenarios while minimizing bandwidth requirements and ensuring data integrity. These capabilities substantially extend the practical utility of the codebook-based encoding system described in the original disclosure, making it suitable for deployment in complex, distributed environments with stringent security, efficiency, and reliability requirements.

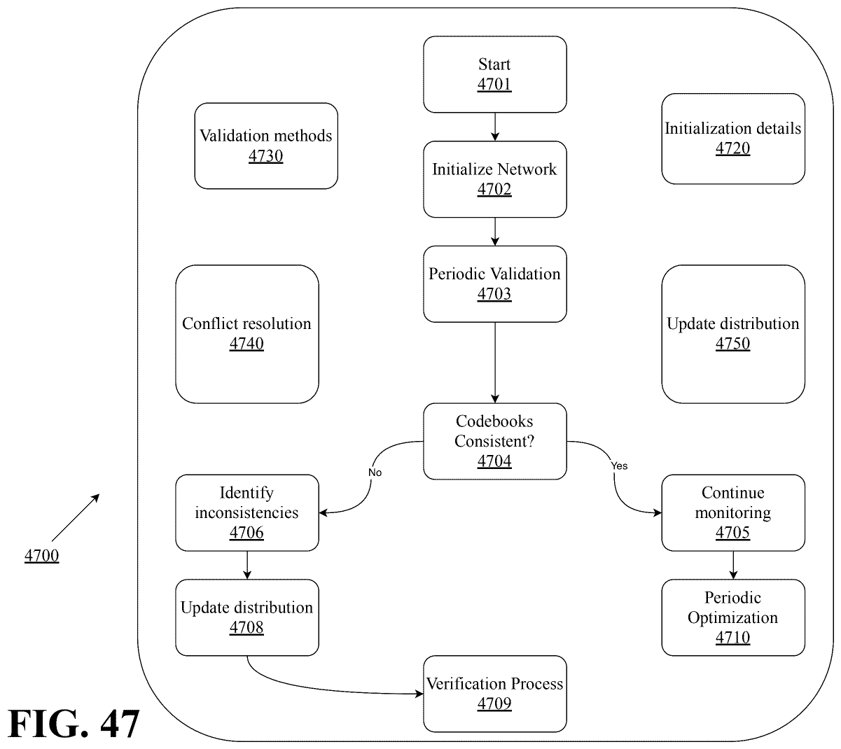

FIG. 47 is a method diagram illustrating a comprehensive method for distributed codebook maintenance 4700 that addresses critical requirements for maintaining consistency, resolving conflicts, and optimizing performance across a network of devices using the encoding system. This method represents a significant advancement over the approaches by providing a systematic framework for maintaining distributed codebooks throughout their lifecycle, ensuring reliable operation across complex deployment scenarios.

The method begins at the start point 4701, proceeding immediately to the initialize network step 4702, where the distributed codebook environment is established. This initialization process includes several key activities detailed in the initialization details 4720, including device discovery protocol that automatically identifies compatible devices in the network, authentication setup that establishes secure communication channels between trusted devices, and initial codebook distribution that provide baseline codebooks to all participating devices. This comprehensive initialization approach ensures that all devices begin with a consistent foundation and secure communication channels, addressing deployment considerations.

Following initialization, the system enters a continuous maintenance cycle beginning with periodic validation 4703, which systematically checks codebook consistency across the distributed environment at scheduled intervals. This validation process employs sophisticated techniques described in the validation methods 4730, including hash comparison that efficiently identifies potential inconsistencies by comparing cryptographic hashes of codebooks, version vector analysis that tracks the evolutionary history of codebooks to identify missing updates, and Merkle tree verification that enables efficient partial validation of large codebooks. These validation techniques represent significant advancements over the approaches, enabling efficient detection of inconsistencies without requiring excessive bandwidth or computational resources.

The consistency decision 4704 evaluates the results of the validation process to determine whether any inconsistencies exist within the distributed codebooks. If the codebooks are consistent across all devices (the “Yes” path), the system proceeds to the continue monitoring step 4705, maintaining its regular validation schedule while the network operates normally. This efficient handling of the consistent case minimizes unnecessary processing and bandwidth consumption during normal operation.

If inconsistencies are detected (the “No” path), the system activates its maintenance processes, beginning with identify inconsistencies 4706, which pinpoints the specific discrepancies between codebooks across the network. This targeted approach allows the system to address only the specific inconsistencies rather than performing unnecessary full codebook synchronizations, significantly improving efficiency.

Once inconsistencies are identified, the system proceeds to conflict resolution 4707, which employs sophisticated strategies detailed in conflict resolution 4740. These strategies include timestamp-based priority that automatically resolves conflicts by selecting the most recent update when concurrent modifications occur, and entry merging techniques that intelligently combine conflicting updates when possible to preserve valuable contributions from multiple sources. This sophisticated conflict management goes well beyond the capabilities implied in the original disclosure, enabling robust operation in complex distributed environments where concurrent modifications are common.

Following successful conflict resolution, the system initiates update distribution 4708, which efficiently propagates the resolved updates to all affected devices in the network. The update distribution methods 4750 details the techniques employed during this phase, including differential updates only that transmit only the specific changes rather than complete codebooks, and gossip protocol that enables robust dissemination even in partially connected networks by allowing devices to relay updates to their neighbors. These distribution approaches minimize bandwidth requirements while ensuring updates reliably reach all devices, addressing efficiency and reliability concerns.

The verification process 4709 confirms the successful application of distributed updates across the network, ensuring that the inconsistencies have been properly resolved. The verification techniques outline the approaches used during this phase, including full consistency check that comprehensively validates the entire codebook on critical updates, and sampling-based verification that efficiently checks representative portions for less critical updates. This verification step provides confidence in the system's consistency while balancing thoroughness against performance considerations.

The periodic optimization 4710 represents an ongoing process that continually improves codebook efficiency independent of the consistency maintenance cycle. The optimization techniques detail the approaches employed during this phase, including pruning unused entries that removes outdated or unnecessary codebook elements to reduce size and improve lookup performance, and frequency-based restructuring that reorganizes codebooks to prioritize commonly used entries. These optimization techniques ensure that the codebooks maintain high performance over time, even as usage patterns evolve.

The distributed codebook maintenance method illustrated in FIG. 47 addresses several critical limitations of the approaches implied in the original disclosure. By providing a comprehensive framework for initializing, validating, updating, and optimizing distributed codebooks, it enables reliable operation across complex network environments. The method's emphasis on efficiency—through differential updates, targeted validation, and periodic optimization—minimizes bandwidth and computational requirements, making it suitable for deployment on resource-constrained devices and bandwidth-limited networks. The sophisticated conflict resolution approaches ensure consistent operation even in scenarios with concurrent modifications, extending the practical utility of the encoding system to collaborative environments. Together, these capabilities significantly enhance the distributed aspects of the encoding system, enabling robust deployment across diverse and challenging operational scenarios.

### Exemplary Computing Environment

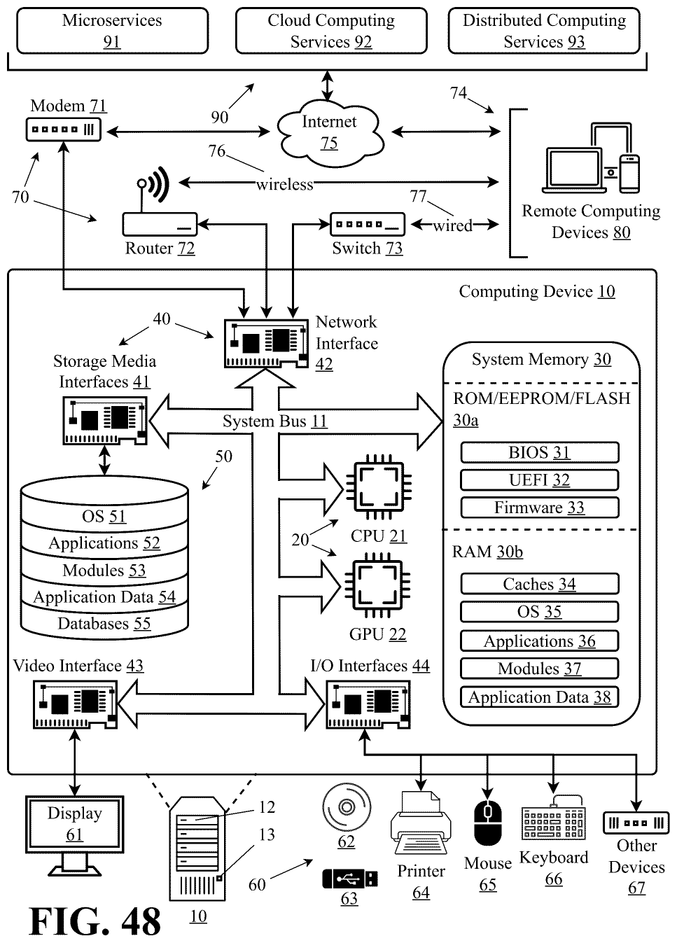

FIG. 48 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, AI accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCIe bus, bypassing the limitations of the SATA interface. Other storage form factors include M.2 SSDs, which are compact storage devices that connect directly to the motherboard using the M.2 slot, supporting both SATA and NVMe interfaces. Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

In FIG. 48, computing device 10 further comprises externally-accessible data ports or connections 13 that enable connection of external peripherals and accessories 60. The system memory 30 includes non-volatile memory 30a which stores BIOS 31, Unified Extensible Firmware Interface (UEFI) 32, and firmware 33. UEFI 32 serves as a modern replacement for BIOS that supports larger hard drives, faster boot times, and more security features. Firmware 33 may comprise a complete operating system and applications for operating computer-controlled devices, particularly in purpose-specific computing environments with limited processing power and storage resources.

The skilled person will be aware of a range of possible modifications of the various aspects described above. Accordingly, the present invention is defined by the claims and their equivalents.

What is claimed is:

1. A computer system for encoding data using mismatch probability estimation, comprising:
a hardware memory, wherein the computer system is configured to execute software instructions stored on nontransitory machine-readable storage media that:
receive a training data set for encoding, the training data set comprising sourceblocks of data;
determine a frequency of occurrence of each sourceblock of the training data set;
calculate a mismatch probability estimate comprising a probability that any given sourceblock in a non-training data set to be later received for encoding will not be a sourceblock that was contained in the training data set, wherein the mismatch probability estimate is dynamically adjusted based on observed data patterns;
generate a mismatch sourceblock representing sourceblocks that were not contained in the training data set, and assign the mismatch probability estimate to the mismatch sourceblock as the frequency of occurrence of the mismatch sourceblock;
generate a codebook from the sourceblocks of the training data set and the mismatch sourceblock using an entropy encoding method wherein codewords are assigned to each sourceblock based on its frequency of occurrence; and
apply context-aware mismatch handling to select an appropriate secondary encoding method based on detected data type.

2. The computer system of claim 1, wherein the software instructions further cause the computer system to:
analyze the context of the data to determine whether the data comprises text, binary, image, or executable code; and
select a context-specific secondary encoding method optimized for the determined data type when a mismatch occurs.

3. The computer system of claim 1, wherein the software instructions further cause the computer system to:
implement a machine learning-based system that processes data characteristics and outputs optimized mismatch probability values;
extract feature vectors from the training data set;
calculate actual mismatch occurrences for the training data set; and
train a neural network to predict optimal mismatch probability values based on the features vectors and actual mismatch occurrence.

4. The computer system of claim 1, wherein the software instructions further cause the computer system to:
monitor real-time data patterns during encoding;
detect changes in data characteristics that would affect optimal mismatch probability values;
dynamically adjust the mismatch probability estimate based on the detected changes; and
apply an adaptive exponentially-weighted moving average formula to calculate updated mismatch probability estimates.

5. The computer system of claim 1, wherein the software instructions further cause the computer system to:
enable codebook training on resource-constrained edge devices;
monitor available resources including CPU, memory, and power usage on the edge devices;
schedule training operations during periods of low resource utilization; and
synchronize trained codebooks with a central server while maintaining data privacy.

6. The computer system of claim 1, wherein the software instructions further cause the computer system to:
generate differential updates containing only the changes between codebook versions;
identify added, removed, and modified codewords when comparing codebook versions;
package the identified changes into a compact delta package; and
transmit only the delta package for codebook synchronization rather than the entire codebook.

7. The computer system of claim 1, wherein the software instructions further cause the computer system to:
implement a federated codebook learning system that enables multiple devices to contribute to a shared codebook while maintaining data privacy;
perform local training on device-specific data without transmitting the raw data;
apply privacy-preserving techniques including differential privacy, secure aggregation, and knowledge distillation to device contributions; and
aggregate device contributions with appropriate weighting based on data quality, device reliability, and contribution importance.

8. The computer system of claim 1, wherein the software instructions further cause the computer system to:
implement a secure codebook synchronization protocol comprising authentication, version exchange, codebook exchange, and verification phases;
authenticate devices using challenge-response mechanisms and device certificates;
exchange version vectors to precisely identify codebook differences;
resolve conflicts between concurrent codebook modifications; and
verify successful synchronization through checksum comparison.

9. The computer system of claim 1, wherein the software instructions further cause the computer system to:
implement a distributed codebook maintenance method comprising initialization, validation, conflict resolution, update distribution, verification, and optimization;
periodically validate codebook consistency across distributed devices;
identify and resolve inconsistencies when detected;
distribute updates using differential packages and gossip protocols;
verify successful update application; and
periodically optimize codebooks by pruning unused entries and restructuring based on usage frequency.

10. A computer-implemented method for encoding data using mismatch probability estimation, comprising the steps of:
receiving a training data set for encoding, the training data set comprising sourceblocks of data;
determining a frequency of occurrence of each sourceblock of the training data set;
calculating a mismatch probability estimate comprising a probability that any given sourceblock in a non-training data set to be later received for encoding will not be a sourceblock that was contained in the training data set, wherein the calculation implements a machine learning model trained to predict optimal mismatch probabilities based on data characteristics;
generating a mismatch sourceblock representing sourceblocks that were not contained in the training data set; and
assigning the mismatch probability estimate to the mismatch sourceblock as the frequency of occurrence of the mismatch sourceblock;
generating a codebook from the sourceblocks of the training data set and the mismatch sourceblock using an entropy encoding method wherein codewords are assigned to each sourceblock based on its frequency of occurrence; and
maintaining codebook consistency across distributed devices through periodic validation and differential updates.

11. The computer-implemented method of claim 10, further comprising:
analyzing the context of the data to determine whether the data comprises text, binary, image, or executable code; and
selecting a context-specific secondary encoding method optimized for the determined data type when a mismatch occurs.

12. The computer-implemented method of claim 10, further comprising:
implementing a machine learning-based system that processes data characteristics and outputs optimized mismatch probability values;
extracting feature vectors from the training data set;
calculating actual mismatch occurrences for the training data set; and
training a neural network to predict optimal mismatch probability values based on the feature vectors and actual mismatch occurrences.

13. The computer-implemented method of claim 10, further comprising:
monitoring real-time data patterns during encoding;
detecting changes in data characteristics that would affect optimal mismatch probability values;
dynamically adjusting the mismatch probability estimate based on the detected changes; and
applying an adaptive exponentially-weighted moving average formula to calculate updated mismatch probability estimates.

14. The computer-implemented method of claim 10, further comprising:
enabling codebook training on resource-constrained edge devices;
monitoring available resources including CPU, memory, and power usage on the edge devices;
scheduling training operations during periods of low resource utilization; and
synchronizing trained codebooks with a central server while maintaining data privacy.

15. The computer-implemented method of claim 10, further comprising:
generating differential updates containing only the changes between codebook versions;
identifying added, removed, and modified codewords when comparing codebook versions;
packaging the identified changes into a compact delta package; and
transmitting only the delta package for codebook synchronization rather than the entire codebook.

16. The computer-implemented method of claim 10, further comprising:
implementing a federated codebook learning system that enables multiple devices to contribute to a shared codebook while maintaining data privacy;
performing local training on device-specific data without transmitting the raw data;
applying privacy-preserving techniques including differential privacy, secure aggregation, and knowledge distillation to device contributions; and
aggregating device contributions with appropriate weighting based on data quality, device reliability, and contribution importance.

17. The computer-implemented method of claim 10, further comprising:
implementing a secure codebook synchronization protocol comprising authentication, version exchange, codebook exchange, and verification phases;
authenticating devices using challenge-response mechanisms and device certificates;
exchanging version vectors to precisely identify codebook differences;
resolving conflicts between concurrent codebook modifications; and
verifying successful synchronization through checksum comparison.

18. The computer-implemented method of claim 10, further comprising:
implementing a distributed codebook maintenance method comprising initialization, validation, conflict resolution, update distribution, verification, and optimization;
periodically validating codebook consistency across distributed devices;
identifying and resolving inconsistencies when detected;
distributing updates using differential packages and gossip protocols;
verifying successful update application; and
periodically optimizing codebooks by pruning unused entries and restructuring based on usage frequency.

19. The computer-implemented method of claim 10, wherein the mismatch probability estimate is calculated using an exponentially-weighted moving average with an adaptive parameter that adjusts based on observed data characteristics and mismatch pattern.

20. The computer-implemented method of claim 10, wherein context-aware mismatch handling is applied by:
analyzing the data context to identify data type;
selecting a context-specific encoding method optimized for the identified data type;
applying the selected encoding method to mismatched sourceblocks; and
ensuring encoding and decoding consistency across the distributed system.
